(19) United States
(12) Patent Application Publication
(10) Pub. No.: US 2002/0001899 A1
(43) Pub. Date: Jan. 3, 2002

(54) Semiconductor integrated circuit device and a method of manufacturing the same

(76) Inventor: Fumitoshi Ito, Higashimurayama (JP)

Correspondence Address: ANTONELLI TERRY STOUT AND KRAUS, SUITE 1800, 1300 NORTH SEVENTEENTH STREET, ARLINGTON, VA, 22209

(21) Appl. No.: 09/870,726

(22) Filed: Jun. 1, 2001

(30) Foreign Application Priority Data
Jun. 15, 2000 (JP) 2000-180004

(51) Int. Cl. H01L 21/8238

(52) U.S. Cl. 438/231

(57) ABSTRACT

A semiconductor integrated circuit device comprises a p-channel MISFET and/or an n-channel MISFET, of which an SRAM cell is constituted and which is arranged to have an offset structure, and MISFET for selection of SRAM cells and MISFET constituting a peripheral circuit of SRAM or a logic circuit which is arranged to have a non-offset structure. At least one of MISFET's constituting an SRAM cell is arranged to take a measure against GIDL (gate induced drain leakage) current.

This invention relates to a semiconductor integrated circuit device and also to a technique of manufacturing the semiconductor integrated circuit device, and more particularly, to a semiconductor integrated circuit device having SRAM (static random access memory) and a technique that is effectively applicable to the manufacture of such a semiconductor integrated circuit as mentioned above.

### TECHNICAL FIELD OF THE INVENTION

SRAM has been employed in various types of electronic devices including portable devices and household appliances because memory cells thereof have an active element for charge supply, so that a re-fresh operation becomes unnecessary with ease in use. With portable devices and household appliances, it is required to reduce a working current of a circuit and a stand-by current in order to reduce consumption power. To this end, in SRAM used in this type of article, most of the memory cells and peripheral circuits are constituted of MIS (metal insulator semiconductor) type semiconductor elements having an excellent low consumption power performance. SRAM, which has memory cells, each constituted of a perfect complementary metal insulator semiconductor field effect transistor (CMIS (complementary MISFET)) made of six MIS-type semiconductor elements, has been accepted from a structural viewpoint as having a very small leakage current when data is held. Thus, SRAM has been frequently used in articles needing battery backup, such as portable devices, household appliances and the like. As to the SRAM, there is disclosed, for example, in U.S. Pat. Nos. 5,754,467 and 5,780,710.

### SUMMARY OF THE INVENTION

We have found hitherto unknown problems involved in the technology of semiconductor integrated circuit devices having SRAM.

More particularly, as the size of a MIS-type semiconductor element is reduced, an internal electric field of a semiconductor increases, under which a gate induced drain leakage (GIDL) current runs in a condition where a drain voltage is applied to, thereby increasing an off current (stand-by current) of the MIS type semiconductor element. This brings about the problem that the consumption power of the semiconductor integrated circuit device having SRAM increases. Especially, the problem becomes serious in view of the fact that, in SRAM having the perfect CMIS-type memory cell, the leakage current in a data-holding state (i.e. in an off state of a selective transistor of the memory cell) is predominant of the GIDL current.

It should be noted that we have searched prior art with respect to GIDL based on the above finding. According to the results of the search, there is disclosed, for example, in Japanese Laid-open Patent Application No. Hei 9(1997)-135029 a technique as a measure against GIDL wherein an impurity used to form a source region and a drain region is introduced into a semiconductor substrate in a condition where a side wall is provided at a gate electrode.

In Japanese Laid-open Patent Application No. Hei 9(1997)-92830, for example, a technique is disclosed in order to cope with GIDL, in which an impurity for forming a source region and a drain region are introduced into a semiconductor substrate in a condition where side walls are provided at opposite sides of a gate electrode.

Moreover, in Japanese Laid-open Patent Application No. Hei 10(1998)-65151, for example, there is disclosed a technique wherein an impurity for formation of LDD (lightly doped drain) and an impurity for a source•drain diffusion layer are introduced into a semiconductor substrate after formation of first and second side walls at opposite sides of a gate electrode as a measure against GIDL.

In Japanese Laid-open Patent Application No. Hei 7(1995)-321320, for example, there is also disclosed a technique of dealing with GIDL wherein an impurity for forming a source region and a drain region is introduced into a semiconductor substrate in a condition where side walls are provided at opposite sides of a gate electrode. In addition, there is disclosed a technique wherein a semiconductor region for LDD whose impurity concentration is relatively low only at a source region side.

Further, in Japanese Laid-open Patent Application No. Hei 8(1996)-228000, for example, there is disclosed a technique as a measure against GIDL wherein the thickness of a gate insulating film portion at the side of a source region is small than a gate insulating film portion at the side of a drain region.

In Japanese Laid-open Patent Application No. Hei 11(1999)-274494, for example, there is disclosed a technique of dealing with GIDL wherein after introduction of an impurity into a portion of a semiconductor substrate corresponding to the end of a gate electrode, a gate insulating film is re-oxidized so that the gate insulating film portions are made relatively thick at the ends of the gate electrode.

In Japanese Laid-open Patent Application No. Hei 11(1999)-163317, for example, wherein there is disclosed a technique as a measure against GIDL wherein after formation of a gate electrode in a pattern on a gate insulating film, gate bird's beaks are formed at both ends of the gate insulating film, thereby making partially thicker at the ends thereof.

Further, in Japanese Laid-open Patent Application No. 2000-12843, for example, there is disclosed a technique in order to cope with the problem of GILD, in which after formation of a gate electrode in a pattern on a gate insulating film, the gate insulating film has once been partially removed by wet etching at ends thereof and is again oxidized, thereby making the gate oxide film partially thicker at the ends thereof.

Further, in Japanese Laid-open Patent Application No. Hei 11(1999)-3990, for example, there is disclosed a structure in order to cope with the problem of GILD, in which after formation of a gate electrode in a pattern on a gate insulating film, the gate insulating film has once been partially removed by wet etching at ends thereof, and a space is provided at the ends of the gate electrode or is buried with a dielectric material.

An object of the invention is to provide a technique wherein a GIDL current can be reduced in a MIS-type semiconductor element constituting a memory cell of SRAM.

Another object of the invention is to provide a technique wherein consumption power of a semiconductor integrated circuit device having SRAM can be reduced.

A further object of the invention is to provide a technique wherein a semiconductor integrated circuit device having SRAM can be operated at a high speed.

A still further object of the invention is to provide a technique wherein the consumption power of a semiconductor integrated circuit device having SRAM can be reduced and high-speed operations can be realized.

The above and other objects and novel features of the invention will become apparent from the description of the specification with reference to the accompanying drawings.

Typical embodiments of the invention are briefly described below.

The invention contemplates to provide a semiconductor integrated circuit device having SRAM wherein among a plurality of filed effect transistors constituting an SRAM cell, at least one metal insulator semiconductor field effect transistor is arranged to cope with the problem of a GIDL current.

The invention also contemplates to provide a semiconductor integrated circuit device having SRAM wherein among a plurality of filed effect transistors constituting an SRAM cell, at least one metal insulator semiconductor field effect transistor is arranged to have an offset structure.

The invention contemplates to provide a semiconductor integrated circuit device having SRAM wherein among a plurality of filed effect transistors constituting an SRAM cell, at least one metal insulator semiconductor field effect transistor is arranged to have an offset structure, and the other metal insulator semiconductor field effect transistors are individually arranged to have a non-offset structure.

The invention contemplates to provide an SRAM cell having a complementary metal insulator semiconductor field effect transistor structure wherein a gate insulating film of at least one first metal insulator semiconductor field effect transistor is thicker than a gate insulating film of a second metal insulator semiconductor field effect transistor that is other than the first metal insulator semiconductor field effect transistor and is supplied with the same source potential as the first metal insulator semiconductor field effect transistor.

Further, the invention contemplates to provide a semiconductor integrated circuit device having SRAM wherein among a plurality of metal insulator semiconductor field effect transistors constituting an SRAM cell, at least one first metal insulator semiconductor field effect transistor has a an impurity concentration of low impurity concentration semiconductor regions in a pair of semiconductor regions for source•drain thereof is lower than an impurity concentration of low impurity concentration semiconductor regions in a pair of semiconductor regions for source•drain of a second metal insulator semiconductor field effect transistor that is other than the first metal insulator semiconductor field effect transistor and is supplied with the same source potential as the first metal insulator semiconductor field effect transistor.

### BRIEF DESCRIPTION OF THE DRAWINGS

FIG. 1 is an illustrating view for defining an offset structure;

FIG. 2 is an equivalent circuit diagram;

FIG. 3 is a graph for calculating the degree of offset obtained by use of the models of FIGS. 1 and 2;

FIG. 4 is a graph for calculating the degree of offset obtained by use of the models of FIGS. 1 and 2;

FIG. 5 is a schematic view showing an n-channel field effect transistor used in the present invention to illustrate a GIDL current;

FIGS. 6(a) and 6(b) are, respectively, a view showing a semiconductor energy band under conditions of A-A line of FIG. 5, and FIG. 6(c) is an enlarged view of FIG. 6(c);

FIG. 7 is an enlarged sectional view of the essential part of FIG. 5 illustrating a leakage current in the field effect transistor of FIG. 5;

FIG. 8 is a graph showing the current-voltage characteristic of a field effect transistor;

FIG. 9(a) is a circuit diagram of an SRAM cell and 9(b) is a plan view showing the layout of a semiconductor integrated circuit device according to one embodiment of the invention;

FIGS. 10(a) and 10(b) are, respectively, a graph showing a current-voltage characteristic of a field effect transistor having an offset structure;

FIG. 11 is a circuit diagram of an SRAM cell of a semiconductor integrated circuit device according to one embodiment of the invention;

FIG. 12 is a circuit diagram of an SRAM cell of a semiconductor integrated circuit device according to another embodiment of the invention;

FIG. 13 is a circuit diagram of an SRAM cell of a semiconductor integrated circuit device according to a further embodiment of the invention;

FIG. 14 is a plan view showing an SRAM cell of the semiconductor integrated circuit device of FIG. 11;

FIG. 15 is a sectional view taken along the line A-A of FIG. 14;

FIG. 16 is a sectional view taken along the line B-B of FIG. 14;

FIG. 17 is a sectional view of an essential part of a semiconductor substrate other than the SRAM of a semiconductor integrated circuit device according to the invention;

FIG. 18 is a sectional view showing a p-channel field effect transistor having an offset structure in the SRAM cell of a semiconductor integrated circuit device according to the invention;

FIG. 19 is a sectional view showing an n-channel field effect transistor having an offset structure in the SRAM cell of a semiconductor integrated circuit device according to the invention;

FIG. 20 is an illustrative view illustrating an example of a size and an impurity concentration of the field effect transistors of FIGS. 18 and 19;

FIG. 21 is a sectional view showing a p-channel metal insulator semiconductor field effect transistor having a non-offset structure in portions other than SRAM of a semiconductor integrated circuit device according to the invention;

FIG. 22 is an illustrative view illustrating an instance of a size and an impurity concentration of the field effect transistor of FIG. 21;

FIG. 23 is a sectional view of an n-channel field effect transistor having a non-offset structure of a semiconductor integrated circuit device according to the invention;

FIG. 24 is an illustrative view illustrating an instance of a size and an impurity concentration of the field effect transistor of FIG. 21;

FIGS. 25(a) and 25(b) are, respectively, a sectional view of an essential part in the course of the manufacture of the semiconductor integrated circuit device according to the one embodiment of the invention;

FIGS. 26(a) and 26(b) are, respectively, a sectional view of an essential part in the course of the manufacture of the semiconductor integrated circuit device subsequent to FIGS. 25(a) and 25(b);

FIGS. 27 (a) and 27(b) are, respectively, a sectional view of an essential part in the course of the manufacture of the semiconductor integrated circuit device subsequent to FIGS. 26(a) and 26(b);

FIGS. 28(a) and 28(b) are, respectively, a sectional view of an essential part in the course of the manufacture of the semiconductor integrated circuit device subsequent to FIGS. 27(a) and 27(b);

FIG. 29(a) is a sectional view showing a field effect transistor having an offset structure in a semiconductor integrated circuit device according to another embodiment of the invention and FIG. 29(b) is a sectional view showing a field effect transistor having a non-offset structure in the semiconductor integrated circuit device;

FIG. 30(a) is a sectional view of a field effect transistor, as a countermeasure against GIDL current, of a semiconductor integrated circuit device according to a further embodiment of the invention, and FIG. 30(b) is a sectional view of a field effect transistor, not as a countermeasure against GIDL current, of the semiconductor integrated circuit device;

FIG. 31(a) is a sectional view of a field effect transistor, as a countermeasure against GIDL current, of a semiconductor integrated circuit device according to a still further embodiment of the invention, and FIG. 30(b) is a sectional view of a field effect transistor, not as a countermeasure against GIDL current, of the semiconductor integrated circuit device;

FIGS. 32(a) and 32(b) are, respectively, a sectional view of an essential part in the course of the manufacture of the semiconductor integrated circuit device of FIGS. 31(a) and 31(b);

FIGS. 33(a) and 33(b) are, respectively, a sectional view of an essential part in the course of the manufacture of the semiconductor integrated circuit device subsequent to FIGS. 32(a) and 32(b);

FIGS. 34(a) and 34(b) are, respectively, a sectional view of an essential part in the course of the manufacture of the semiconductor integrated circuit device subsequent to FIGS. 33(a) and 33(b); and

FIGS. 35(a) and 35(b) are, respectively, a sectional view of an essential part in the course of the manufacture of the semiconductor integrated circuit device subsequent to FIGS. 34(a) and 34(b).

### DETAILED DESCRIPTION OF THE PREFERRED EMBODIMENTS

Prior to illustration of the embodiments of the invention, the fundamental meanings of several terms used herein are described below.

1. The term “semiconductor integrated circuit device” used herein means not only a device merely formed on a single crystal silicon, but also those devices formed on other types of substrates such as an SOI (silicon on insulator) substrate, a substrate for manufacturing a TFT (thin film transistor) liquid crystal and the like unless otherwise indicated.

2. The semiconductor wafer (semiconductor substrate) may be sometimes called semiconductor integrated circuit wafer or merely wafer, and this term means a silicon or other semiconductor single crystal substrate (usually in a substantially flat, disk form), a glass substrate, other types of insulating, semi-insulating or semiconductor substrates, and composite substrates thereof. It will be noted that part or whole of a substrate surface, or part or whole of a gate electrode may be formed of other type of semiconductor such as an alloy of polysilicon or single crystal silicon and germanium (hereinafter referred to as SiGe), for example.

3. A semiconductor chip (semiconductor substrate) may be called semiconductor integrated circuit chip or merely chip and this term means a semiconductor wafer, which is obtained after completion of a wafer process (which may be sometimes called pre-step) and subsequently divided into unit circuits.

4. The term “offset structure” means such a structure that the channel side ends of a pair of semiconductor regions for source•drain of a field effect transistor are arranged at positions kept away from (or shifted from) the opposite ends of a gate electrode so as not to be superposed with the gate electrode within a range not impeding the operation of the field effect transistor. The term “non-offset structure” used herein means an ordinary source•drain structure of a field effect transistor wherein the channel side ends of a pair of semiconductor regions for the source•drain are arranged substantially in coincide with the opposite ends of a gate electrode, or are so arranged as to be superposed, in plane, with part of the gate electrode. It will be noted that the term “source•drain” may sometimes include a so-called LDD (lightly doped drain) wherein a semiconductor region having a relatively low impurity concentration is provided at a channel side.

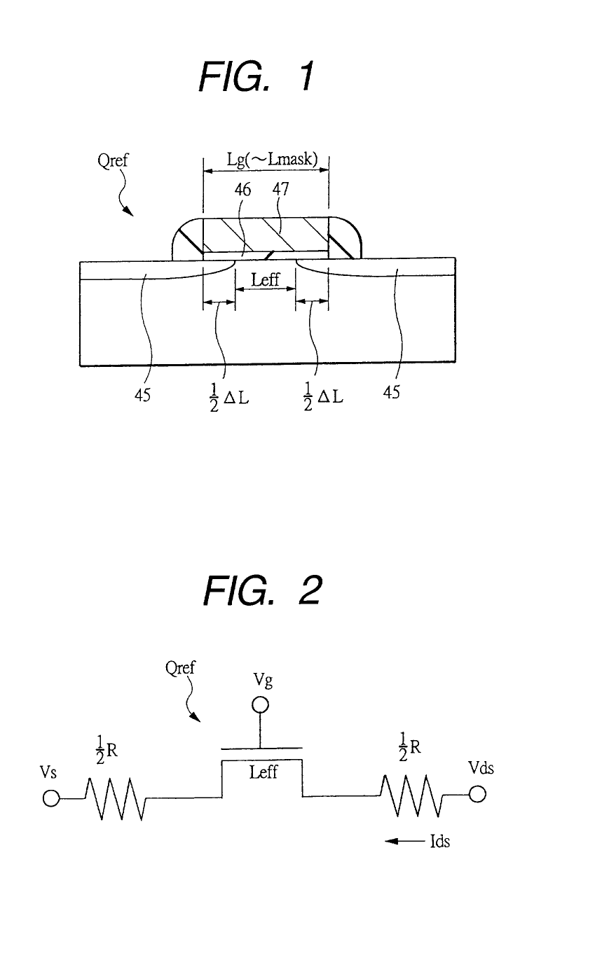

The term “degree of offset” can be defined in the following way. FIGS. 1 and 2 are, respectively, a schematic sectional view showing a MIS•FET (metal insulator semiconductor field effect transistor) Qref, which is a typical of a field effect transistor, and a schematic equivalent circuit diagram of the MIS•FET Qref. The MIS•FET Qref has a pair of semiconductor regions 45 for source•drain and a gate insulating film 46 and a gate electrode 47. Indicated by symbol Lg is a gate length, by L mask is a mask size, by Leff is an effective channel length, by ΔL is a degree of offset, by Vg is a gate voltage, by Vs is a source voltage, by R is a resistance, by Vds is a drain voltage, and by Ids is a drain current, respectively.

The degree of offset ΔL is defined as shown in FIGS. 1 and 2. The degree of offset ΔL is obtained by calculation from a Vg−Ids wave form in a linear region.

### (1) Channel Resistance Method

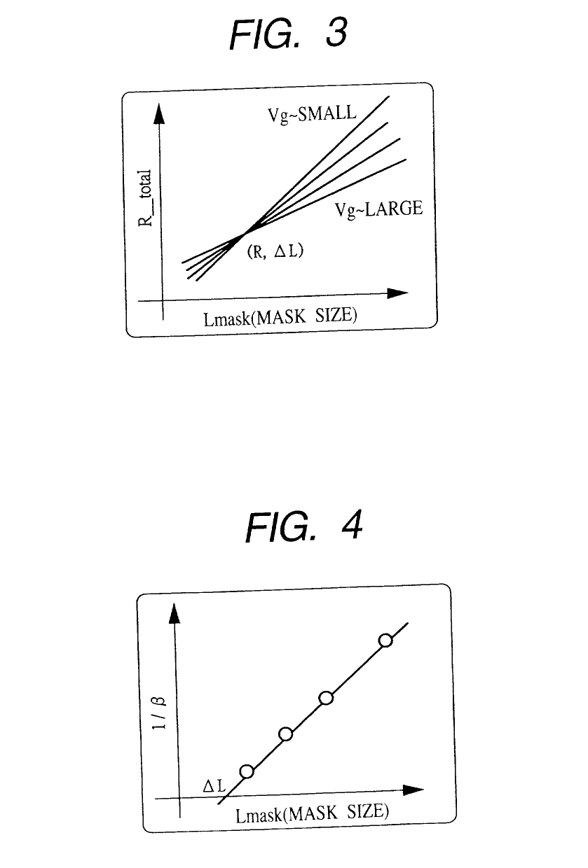

Channel resistance Rtotal including a parasitic resistance R is represented in the following equation. Rtotal=R+(Lmask−ΔL)/(Leff·Cox·W(Vg—Vth—mVds)/2). In the equation, Cox represents a capacitance of a gate insulating film, W represents a gate width, Vth represents a threshold voltage and m is a bulk charge effect constant (m>l). When a Vg−Id characteristic in the linear region of MIS•FET's having different gate lengths is measured from the equation, there are obtained plots as shown in FIG. 3. As shown in the figure, the respective plots are intersected at the point of (R, ΔL) for different gate lengths, so that the degree of offset ΔL can be obtained. As for the details of this method, reference should be made to J. G. J. Chern, P, Chang, R. F. Motta, and N, Gadinho (1980), “A new method to determine MOSFET channel length” IEEE Electron Device Lett., ED-1, p. 170.

### (2) Shift and Ratio Method

Using a value of δ at which r(δ, Vg)=Sⁱ (Vg)/Sⁱ (Vg−δ) becomes constant when dRⁱ total/dVg=L¹eff·df(Vb−Vthⁱ)/dVg=Sⁱ(Vg) is established using the above equation Rtotal, ΔL and R are calculated. As for the details of this method, reference should be made to Y, Taur D. S. Zicherman, D, R. Lombardi, P. J. Restle, C. H. Hsu, H. I. Hanafi, M. R. Wordeman, B. Davari, and G. G. Shahidi (1992), “A new shift and ratio method for MOSFET channel length extraction”, IEEE Electron Device Lett. ED-13, p. 267.

### (3) Mobility Degradation Method

The Vg−Id waveform is fitted into the equation of Ids=(β(Vg−Vth)Vds)/(1+α(Vg−Vth)) that is an equation of Ids in a linear region taking the degradation of mobility and parasitic resistance R into consideration, thereby obtaining α, Vth and β. Here, β is plotted as shown in FIG. 4. This is performed for different gate lengths Lg.

In the following embodiments, individual description may be divided into a plurality of sections or embodiments for convenience's sake, if necessary. Unless otherwise indicated, they are not mutually independent, but one may be in the relation of variations, details or supplemental statements of part or the whole of others.

In the following embodiments, where reference is made to specific numbers or parameters of elements (including the number, value, amount, range and the like), such specific numbers or parameters should not be construed as limiting thereto unless indicated so and except the case where limitation is apparently, principally placed on the specific numbers or parameters. The use of a larger or smaller number of intended elements may be within the scope of the invention.

All elements or steps set out in the following embodiments are not always essential unless indicated so or except the case where they are principally, apparently essential.

Likewise, where reference is made particularly to the shape, positional relationship of elements or members and the like in the following embodiments, a substantially similar or analogous shape or positional relationship is within the scope of the invention unless indicated so or except the case where it should not be principally, apparently included. This is true of the numerical values and ranges indicated in the present specification.

It will be noted that like reference numerals indicate like members or parts throughout the accompanying drawings illustrating the embodiments of the invention.

In the embodiments, MIS•FET, which is typical of field effect transistors, is hereinafter abbreviated merely as MIS. Likewise, a p-channel MIS•FET is abbreviated as pMIS and an n-channel MIS•FET is abbreviated as nMIS.

### Embodiment 1

Prior to description of Embodiment 1, hitherto unknown technical problems checked by us (which may be sometimes referred to as inventor-checked technique) are first described.

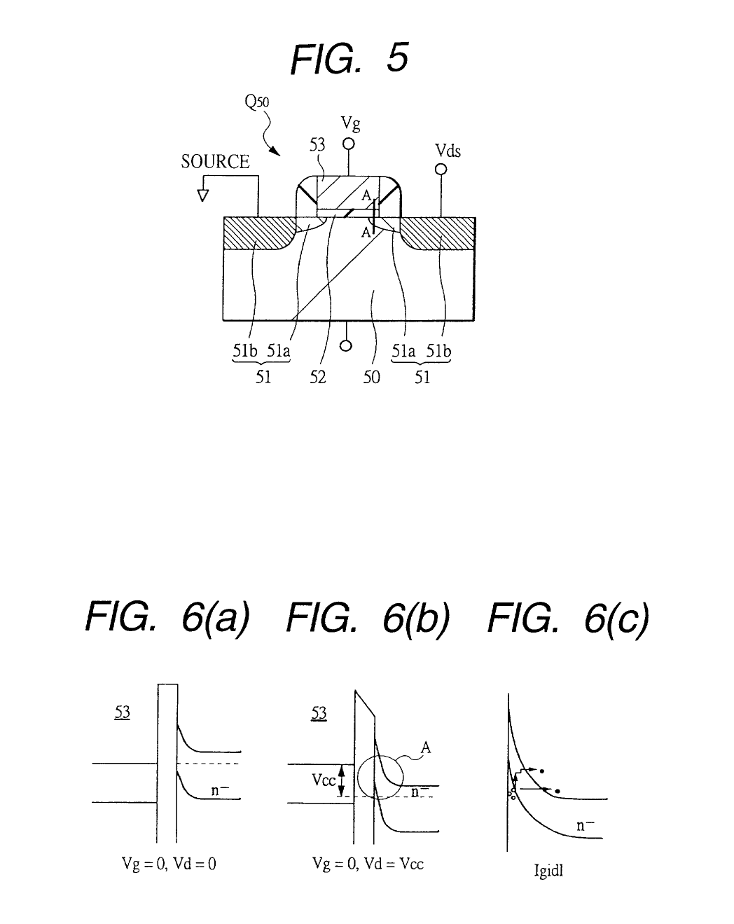

FIG. 5 is a sectional view showing an instance of MIS Q50 in a semiconductor integrated circuit device having SRAM used for an inventor-checked technique. MIS Q50 has a pair of semiconductor region 51 for source•drain formed in a semiconductor substrate 50, a gate insulating film 52, and a gate electrode 53. The pair of semiconductor regions 51 has a semiconductor region 51a provided at a channel side and has a low impurity concentration, and a semiconductor region 51b provided outwardly thereof (in a direction kept away from the gate electrode 53) and has a high impurity concentration. The low impurity concentration semiconductor region 51a is a region constituting a so-called LDD structure, and in order not to lower an on current of MIS or increase a working speed of the semiconductor integrated circuit device, has such a structure (a non-offset structure) that part thereof is superposed in a plane the gate electrode 53 at opposite ends thereof.

FIGS. 6(a), to 6(c) are, respectively, a sectional view showing a semiconductor energy band, taken along line A-A in the case where MIS Q50 is assumed to be nMIS. FIG. 6(a) shows the case where gate voltage Vg=0 V and drain voltage Vd=0V, FIG. 6(b) shows the case where gate voltage Vg=0 and drain voltage Vd=a source voltage Vcc at a higher potential side, and FIG. 6(c) is an enlarged view of area A in FIG. 6(b). As the element sizes of the semiconductor integrated circuit device decrease, the internal electric field of the semiconductor becomes high, under which a tunnel current between bands, i.e. GIDL (gate induced drain leakage) current Igidl passes in a state where the source voltage VCC is applied to as a drain voltage (FIGS. 6(b) and 6(c)). This brings about an increasing off current of MIS Q50 (i.e. a stand-by current passing upon standing-by of MIS Q50), the consumption power of the semiconductor integrated circuit device having SRAM increases.

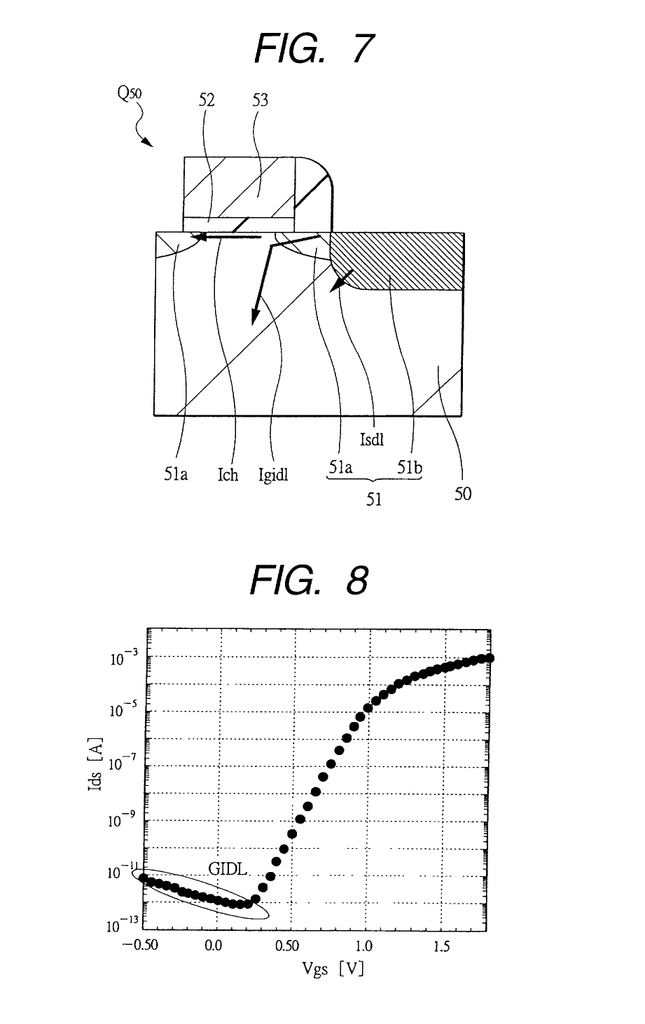

FIG. 7 is an enlarged sectional view of an essential part of MIS Q50 of FIG. 5. The GIDL current is liable to pass through a portion where part of the low impurity concentration region 51a is superposed, in a plane, with the gate electrode 53. It should be noted that, in FIG. 3, symbol Ich indicated a channel current and symbol Isdl indicates a leakage current between the source•drain at the time of stand-by or the like. This leakage current Isdl can be coped with the optimization of an impurity concentration profile at the pn junction between the high impurity concentration semiconductor region and the semiconductor substrate.

FIG. 8 shows a current-voltage characteristic of MIS Q50 shown in FIGS. 5 and 7. The current at gate voltage Vg=0V is predominant of the GIDL current. More particularly, when MIS Q50 is off (or is stood by), the leakage current is predominant of the GIDL current.

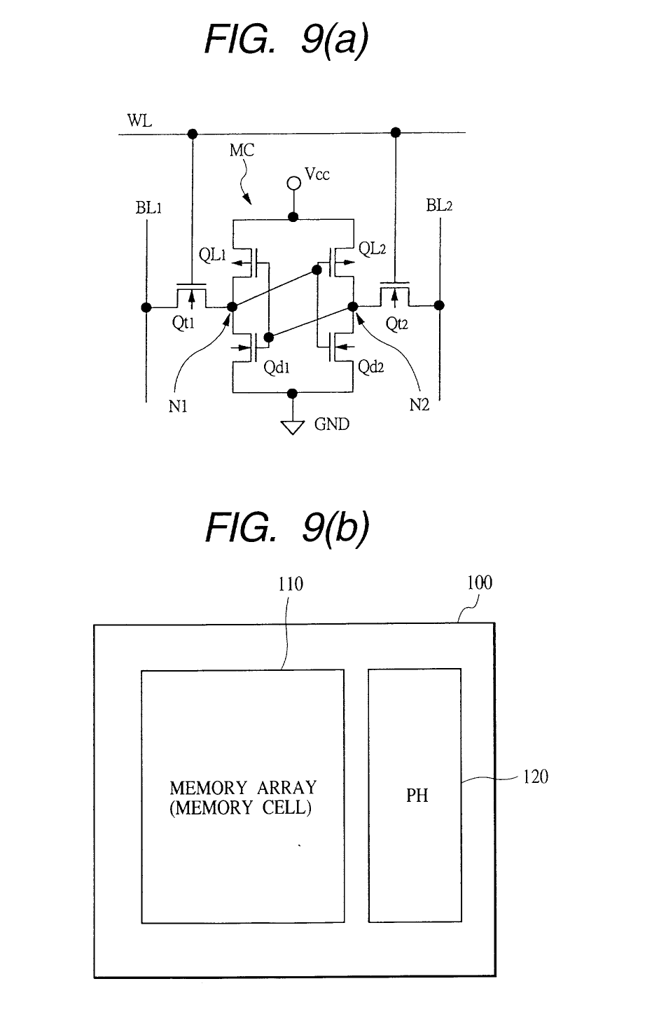

FIG. 9(a) shows a circuit diagram of SRAM cell MC of an ordinary complete CMIS (complementary MIS) type. This SRAM cell MC has six MIS's including a pair of complementary bit lines BL1, BL2, a pair of MIS's Qd1, Qd2 for drive provided in the vicinity of the intersection with a word line WL, a pair of MIS′ QL1, QL2 for load resistance, and a pair of MIS's Qt1, Qt2 for selection. Signals mutually reversed are transmitted to the pair of complementary bit lines BL1, BL2. It will be noted that SRMA cell MC has the same circuit as the SRAM cell MC of Embodiment 1 appearing hereinafter.

In the SRMA cell of such a complete CMIS type as mentioned above, which differs from an SRAM cell of a 4MIS type using a high resistance polysilicon or the like as a high resistance load, a leakage current in an off state (i.e. a data holding state) of the MIS's Qt1, Qt2 for selection is predominant of the GIDL current. For instance, where a node N1 of FIG. 9 is in a high state and a node N2 is in a low state, a problem is involved in the GIDL current in the MIS Qd1 for drive, the MIS Qt1 for selection and the MIS QL2 for load. On the other hand, where the node N1 is low and the node N2 is high, the GIDL current in the MIS Qd2 for drive, the MIS Qt2 for selection and the MIS QL1 for load presents a problem. This problem is especially serious in the MIS's QL1 and QL2 for load constituted of pMIS. In general, when the impurity concentration in the semiconductor regions for source•drain of MIS is at a certain or higher level, the energy band is unlikely to be bent (see FIGS. 6(a) to 6(c)), so that the GIDL current is difficult to occur. However, with pMIDS, when the impurity concentration is made high, the leakage current between the source•drain is apt to occur, thereby presenting a punch-through problem. Thus, it is not possible to make a high impurity concentration. Eventually, the GIDL current is likely to occur in pMIS.

In such an SRAM 100, as shown in FIG. 9(b), the area of a memory cell (memory array 100) occupied in the area of a semiconductor chip 100 generally exceeds 60%, so that a ratio of consumption power for a holding current of the SRAM cell MC to total consumption power of SRAM is very large. Accordingly, with SRAM having a plurality of SRAM cells of the complete CMIS type, an increase in consumption power in a date-holding state (stand-by state) becomes a problem to solve. There is a tendency to mount a greater number of memory cells in SRAM of a microprocessor, and thus, it is a serious problem how to lower consumption power. It will be noted that in FIG. 9(b), symbol PH indicates a peripheral circuit other than a memory cell.

According to our studies, in order to reduce the GIDL current, the following methods are effective. Firstly, a plane superposed portion of the semiconductor regions for source•drain of MIS (the low impurity concentration semiconductor regions) and the gate electrode is reduced in area (or no superposed portion is formed to provide a so-called offset structure). Secondly, the gate insulating film of MIS is made thick. Thirdly, the impurity concentration in the low impurity concentration regions for source•drain of MIS is further reduced. In any of these methods, however, the on-current of MIS (drain current) lowers, resulting in a low working speed of the semiconductor integrated circuit device.

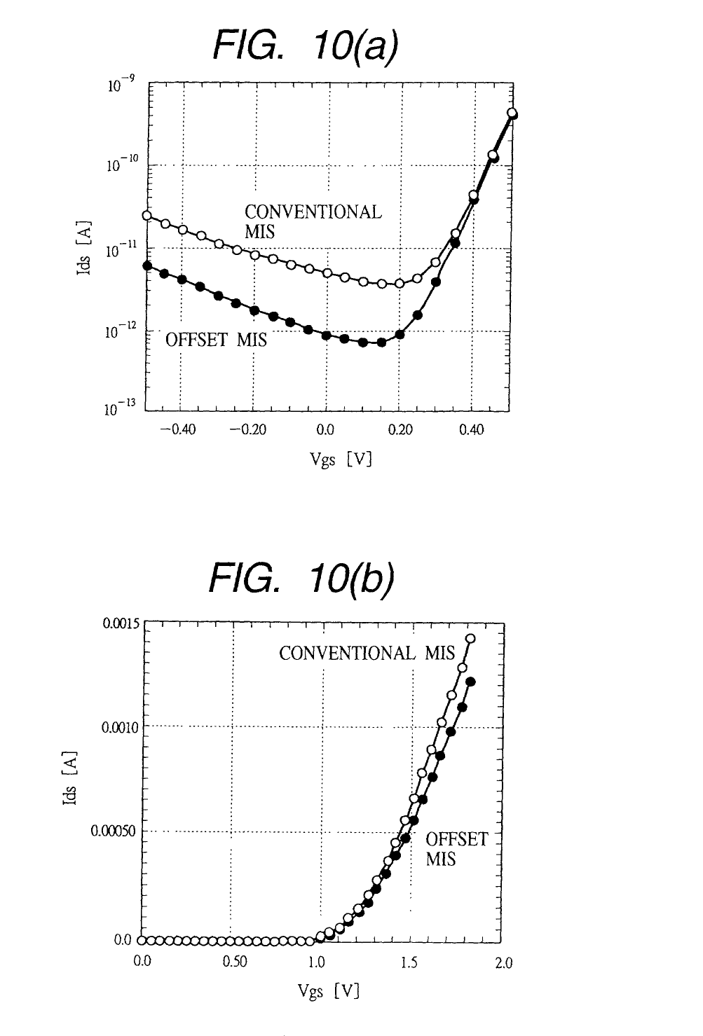

FIGS. 10(a) and 10(b), respectively, show a current-voltage characteristic of MIS having such an offset structure a set out above. It will be noted that in FIGS. 10(a), 10(b), solid circle (●) indicates offset MIS and circle (◯) indicates ordinary MIS. As shown in FIG. 10(a), although with the offset MIS, the GIDL current can be reduced, the on current lowers as is particularly shown in FIG. 10(b). More particularly, when the SRAM having the offset structure is applied to all MIS's constituting the SRAM, the GIDL current of the SRAM cells can be reduced, but the working speed of peripheral circuits for carrying out reading, writing and the like of data become slow, thus making it difficult to realize a high-speed operation. Where the gate insulating film of all MIS's constituting SRAM is made thick, an on current lowers in inverse proportion to the thickness of the insulating film. Moreover, where the degree of plane superposition between the low impurity concentration semiconductor region and the gate electrode of all MIS's constituting SRAM is reduced or where the impurity concentration in the low impurity concentration semiconductor regions is lowered, a parasitic resistance becomes high and the on current lower in both cases, making it difficult to realize the high-speed operation of SRAM.

In Embodiment 1, the source•drain of at least one MIS in the SRAM cell is arranged as an offset where logic circuits exist in a peripheral circuit other than the SPAM cell or in the same semiconductor chip, the source•drain of MIDS of the logic circuit is made non-offset. In this arrangement, the GIDL current of the SRAM cell at the time of stand-by can be lowered in a simple SRAM or a semiconductor integrated circuit device having SRAM, and thus, low consumption power can be realized. In addition, the working speed in the peripheral circuit of SRAM or other logic circuit can be increased, thereby ensuring a high-speed operation of the semiconductor integrated circuit device.

Next, a specific example of a semiconductor integrated circuit device, to which the concept of the invention is applied, is described. The semiconductor integrated circuit device of Embodiment 1 is one which is directed, for example, to portable electronic devices drive with a cell and requiring low consumption power, such as SRAM, SRAM-built-in microprocessors (MPU) for a controller for portable devices, large capacitance SRAM-built-in microprocessors (MPU or CPU), and the like. It will be noted that the minimum effective channel length of MOS's constituting a semiconductor integrated circuit device is, for example, at 0.14 μm or below. Cells used for this purpose include, for example, a lithium ion secondary cell, a metallic lithium secondary cell, a lithium polymer secondary cell and the like various types of cells for small-sized portable electronic devices.

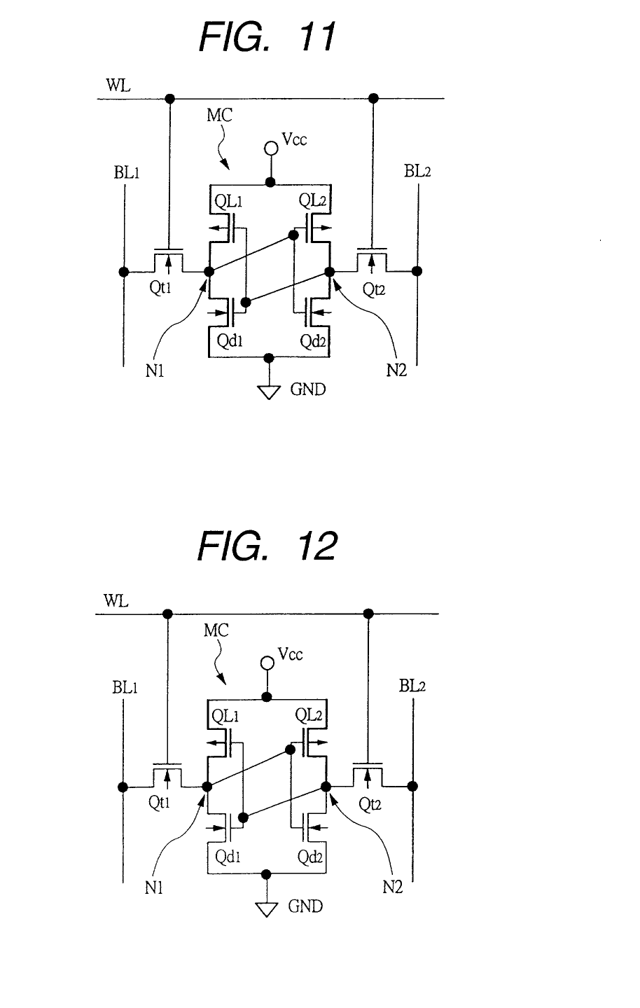

An instance of a circuit structure of an SRAM cell of a semiconductor integrated circuit device according to Embodiment 1 is described with reference to FIG. 11. It will be noted that the thick lines indicate portions corresponding to the offset structure.

In the semiconductor integrated circuit device of Embodiment 1, moderate-speed SRAM is used, for example. A SRAM cell MC is located in the vicinity of intersections between a pair of complementary bit lines BL1, BL2 and a word line WL. Mutually inverse signals are transmitted to the pair of complementary bit lines BL1, BL2.

This SRAM cell MC is constituted, for example, of a complete CMIS-type SRAM cell and includes six MIS's including a pair of MIS's Qd1, Qd2 for drive, a pair of MIS's QL1, QL2 for load resistance, and a pair of MIS's Qt1, Qt2 for selection. The MIS's Qd1, Qd2 for drive and the MIS's Qt1, Qt2 for selection are, respectively, constituted of nMIS and the MIS's QL1, QL2 for load resistance are, respectively, constituted of pMIS.

The pair of MIS's Qd1, Qd2 for drive and the pair of MIS's QL1, QL2 constitute a flip-flop circuit. This flip-flop circuit is a memory element for memorizing one-bit information “1=high or 0=low), and is electrically connected at one end thereof (MIS QL1, QL2 sides for load resistance) to an electrode, to which a source voltage Vcc at a relatively high potential side is applied, and is electrically connected at the other end thereof (MIS's Qd1, Qd2 sides for drive) to an electrode, to which a source voltage Vcc at a relatively low potential (ground potential) side is applied. It will be noted that the source voltage at the high potential side is, for example, at about 1.8 V or about 1.5 V, and the source voltage at the low potential side is, for example, at about 0 V.

The pair of MIS's QL1,. QL2 for selection is a switching element wherein the flip-flop circuit for the memory element is electrically connected to or disconnected from the bit lines BL1, BL2, and intervenes between the input and output terminals (nodes N1, N2) of the respective flip-flop circuits and the bit lines BL1, BL2. It will be noted that the gate electrodes of the pair of MIS's Qt1, Qt2 for selection are connected to the word line WL.

In Embodiment 1, as shown in FIG. 11 as thick lines, the pair of MIS's Qd1, Qd2 for drive and the source•drain of the pair of MIS's QL1, QL2 are depicted as the offset structure. The reason why the MIS of the SRAM cell MC is arranged as the offset structure is that MIS's in the SRAM cell MC work only by supplying a current corresponding to a leakage current of a holding node or by the capability of current drive for permitting a light change of a potential of the bit line BL. Thus, great drive power is not required in comparison with a peripheral circuit, a logic circuit or the like. In a holding state where the word line WL is in a low state, a drain voltage is invariably applied to MIS's of either of the pair of MIS's QL1, QL2 for load and either of the pair of MIS's Qd1, Qd2 for drive, so that an off current passes. However, assuming that the off currents of nMIS and pMIS are at the same level and that an off current per unit MIS can be reduced to ½ by adoption of a MIS having an offset structure, it becomes possible to save a consumption current by about 50% per unit SRAM cell MC of FIG. 11. More particularly, according to Embodiment 1, the consumption power of the semiconductor integrated circuit device having SRAM can be reduced to a half or more of the case where any offset structure is not adopted at all. Accordingly, when such a semiconductor integrated circuit device is used in a cell-driven portable electronic device, the working time of the portable electronic device can be prolonged. Thus, the inconveniences that power supply is lost in use of a portable electronic device, or a cell exchange becomes necessary can be reduced in number, or the number of cell exchanges can be reduced.

Where there exist logic circuits other than SRAM in a pair of MIS's Qt1, Qt2 for selection, a peripheral circuit for SRAM, and the same semiconductor chip, the source•drain of MIS constituting the logic circuits is arranged to have a non-offset structure (i.e. an ordinary MIS structure). When the pair of MIS's Qt1, Qt2 including the MID constituting the peripheral circuit of SRAM are arranged to have a non-offset structure (i.e. an ordinary MIS structure), high-speed read-out and write operations can be realized. In this way, a satisfactory processing speed of a portable electronic device having the semiconductor integrated circuit device of Embodiment 1 is ensured. A quick response of the portable electronic device to a given operation of an operator can be obtained.

It should be noted that the application of an offset structure is not limited to those set forth hereinabove, and various variations may be made thereto. For instance, as shown in FIG. 12, a pair of MIS's QL1, QL2 for load resistance may be arranged as having an offset structure (as indicated by thick lines), and if circuits other than SRAM exist in a pair of MIS's Qd1, Qd2 for drive, a pair of MIS's Qt1, Qt2, a peripheral circuit of SRAM and the same semiconductor chip, MIS's constituting the logic circuits may be arranged as having a non-offset structure. With the structure shown in FIG. 12, MIS's coping with the off current are reduced in number over the structure shown in FIG. 11, and where an off current of pMIS is relatively large in comparison with that of nMIS, an effect of reducing the off current is great. The pair of MIS' Qt1, Qt2 including the peripheral circuit of SRAM and the like are arranged in the form of a non-offset structure (i.e. an ordinary MIS structure), so that a high-speed operation of the semiconductor integrated circuit device can be realized, like the case of FIG. 11.

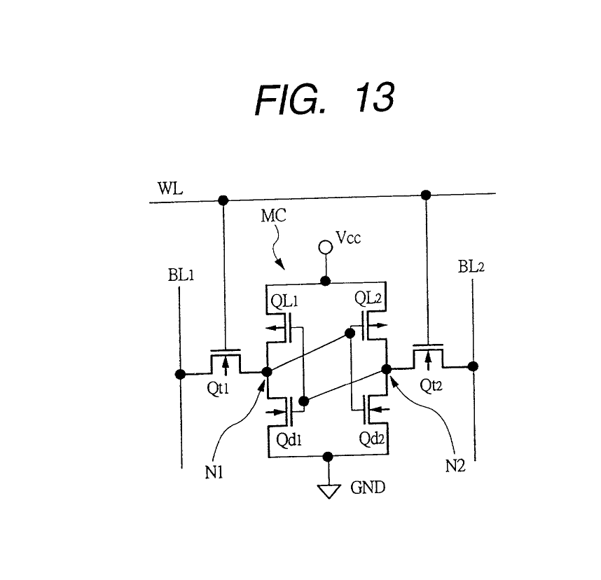

As another instance, as shown in FIG. 13, where all MIS's of SRAM cell MC, i.e. a pair of MIS's QL1 and QL2 for load resistance, a pair of MIS's Qd1 and Qd2 for drive, and a pair of MIS's Qt1 and Qt2 for selection are, respectively, arranged as having an offset structure (indicated by thick lines) and there exist circuits other than SRAM in the peripheral circuit of SRAM and the same semiconductor chip, MIS's constituting the logic circuits may be arranged as having a non-offset structure. In a holding state where the word line WL is in a low state, either of MIS's Qt1, Qt2 for selection is in a state where a drain voltage is applied to, along with either of MIS's QL1, QL2 for load and either of MIS's Qd1, Qd2, so that an off current passes. Accordingly, with FIG. 13 in which all MIS's of SRAM cell MC individually have an offset structure, it becomes possible to reduce consumption power over the case of FIG. 11. Further, the pair of MIS's QL1, Qt2 are, respectively, formed as an offset structure, a working speed lowers slightly. Nevertheless, the peripheral circuit and the logic circuits, respectively, have a non-offset structure, so that the working speeds of the peripheral circuit and the logic circuits do not lower. Accordingly, when using the structure of FIG. 13, the working speed of the semiconductor integrated circuit device does not lower significantly.

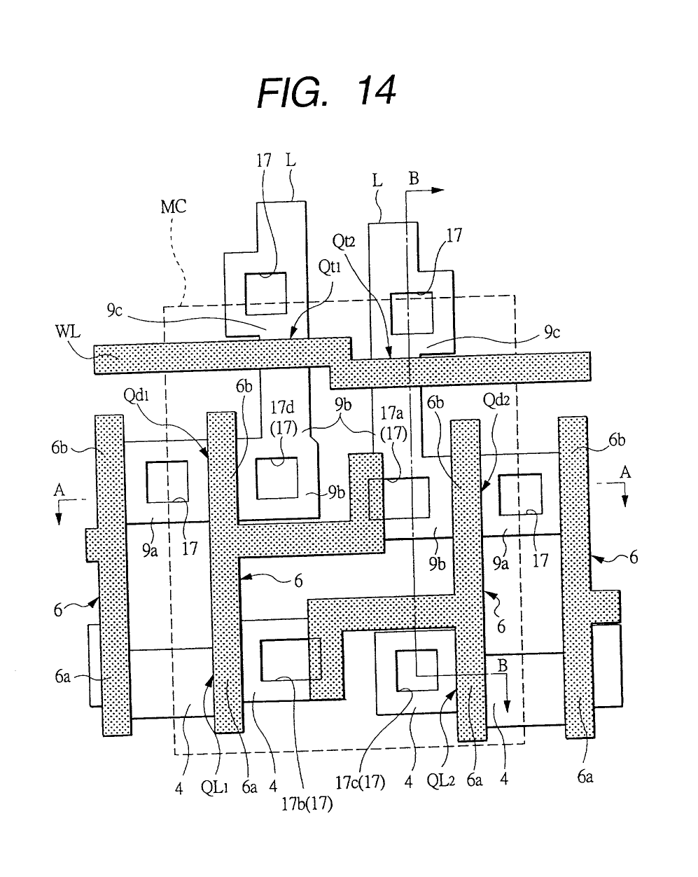

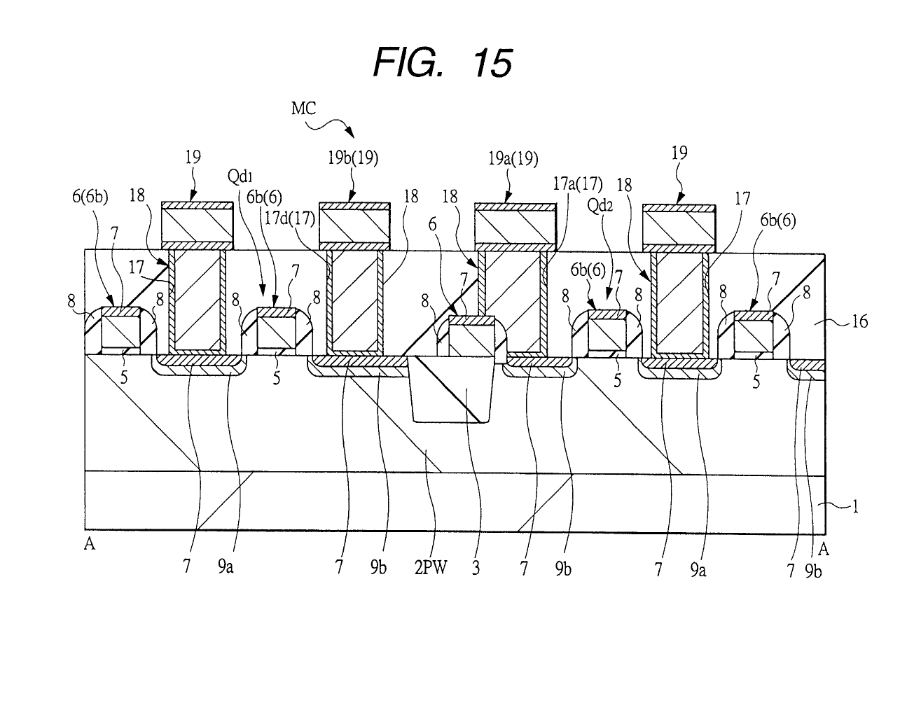

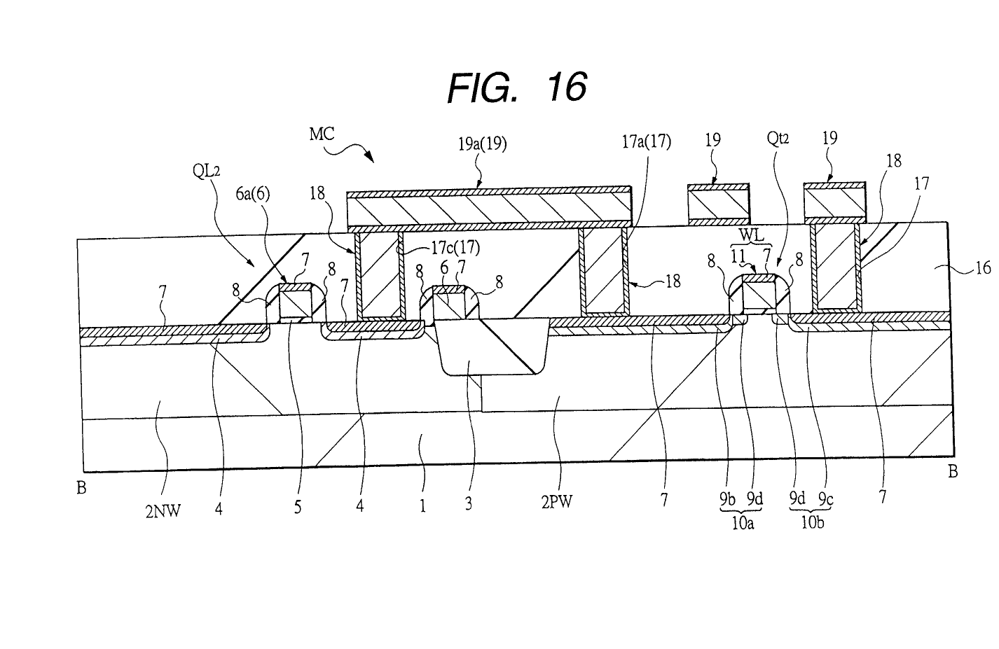

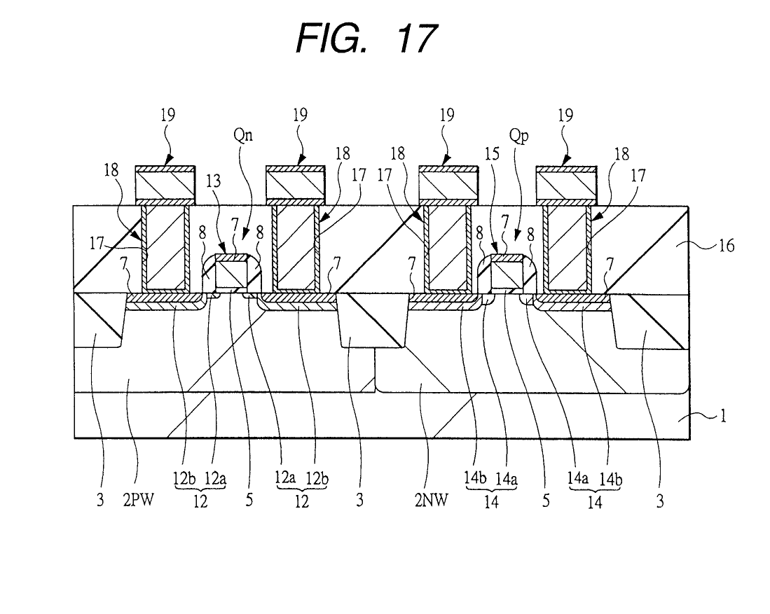

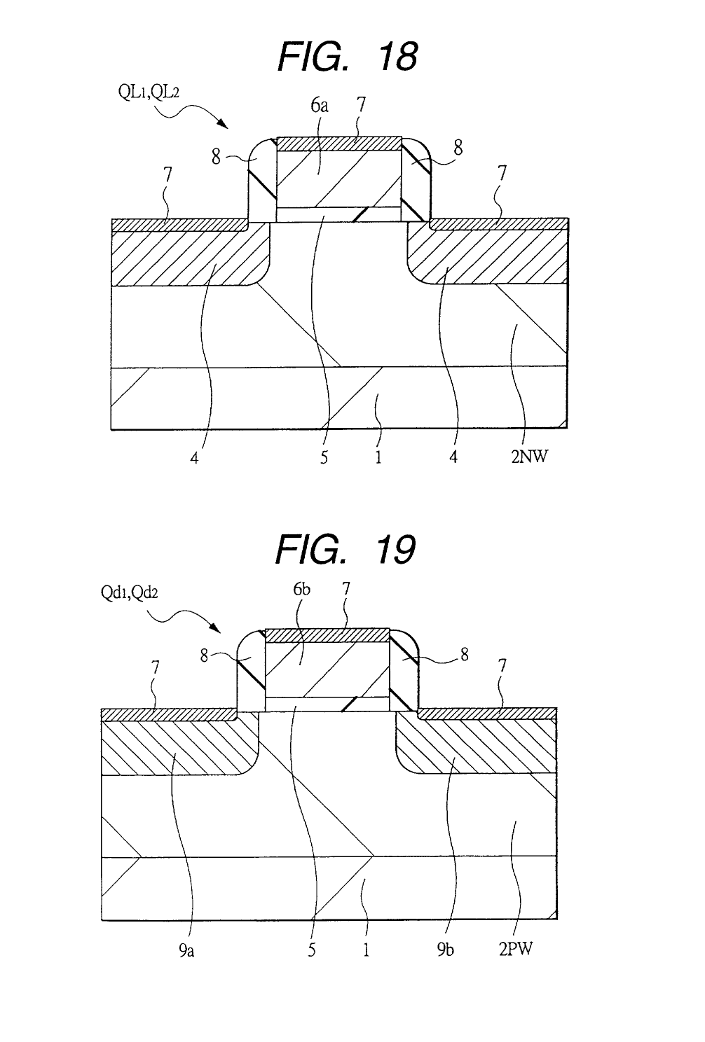

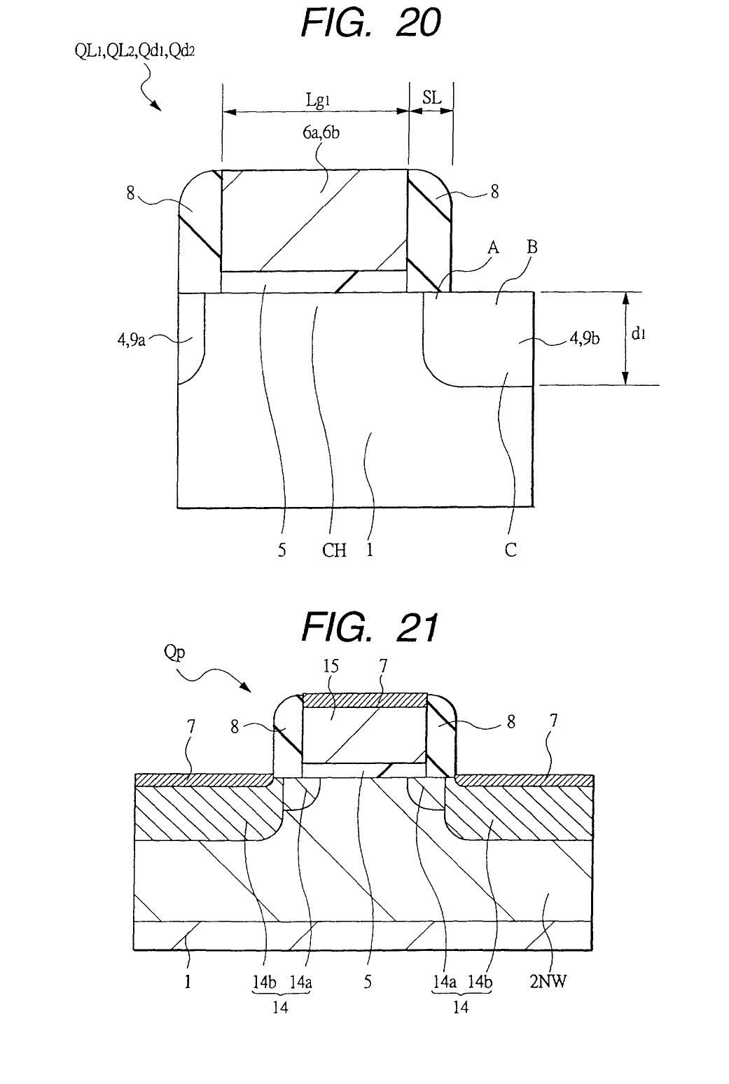

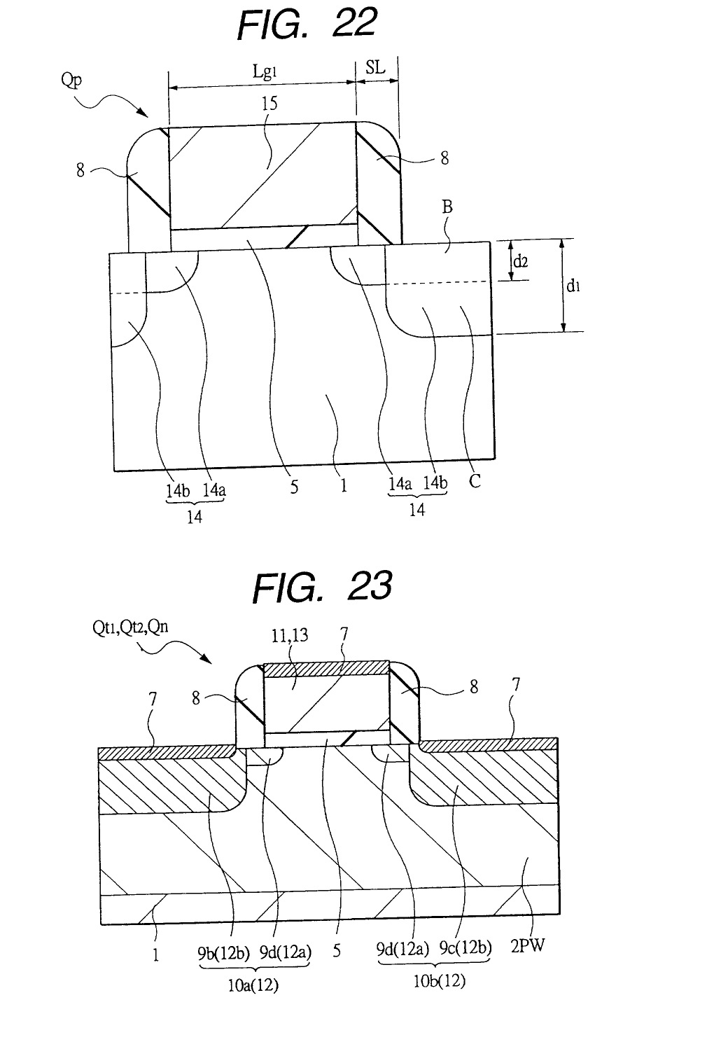

Next, the examples of a device structure of the semiconductor integrated circuit device according to Embodiment 1 of the invention are described with reference to FIGS. 14 to 24. FIG. 14 is a plan view showing the SRAM cell MC, FIG. 15 is a sectional view taken along line A-A of FIG. 14, and FIG. 16 is a sectional view taken along line B-B of FIG. 14. FIG. 17 is a sectional view of MIS constituting a logic circuit when a logic circuit exists in a peripheral circuit or the same semiconductor chip of SRAM. FIGS. 18 and 19 are, respectively, an enlarged sectional view of an essential part of MIS of an offset structure in the SRAM cell MC, and FIG. 20 is an illustrative view of an example of a size and an impurity concentration at the respective portions of MIS of FIGS. 18 and 19. FIGS. 21 and 23 are, respectively, enlarged sectional views of MIS's having a non-offset structure in a logic circuit when a logic circuit exists in a peripheral circuit of SRAM and the same semiconductor chip and also in a SRAM cell. FIGS. 22 ad 25 are, respectively, illustrative views showing a size and an impurity concentration in the respective portions of the MIS's of FIGS. 21 and 23.

A semiconductor substrate 1 constituting a semiconductor chip is made, for example, of a p-type silicon (Si) single crystal. A p-well 2PW and an n-well 2NW are formed in the semiconductor substrate 1. The p-well 2PW is formed by distributing an impurity, such as boron (B) or the like, which extends from the main surface of the semiconductor substrate 1 (i.e. an element-forming surface) to a given depth, and the n-well 2NW is formed by distributing an impurity, such as phosphorus (P) or arsenic (As), to extend from the main surface of the semiconductor substrate 1 to a given depth.

The semiconductor substrate 1 is formed in the main surface thereof, for example, with a grooved isolation portion (trench isolation) and an active region L surrounded with the trench isolation in a plane. The grooved isolation portion 3 is formed by burying an insulating film, such as, for example, silicon oxide (SiO₂) or the like, in a groove formed in the semiconductor substrate 1. The isolation portion is grooved, so that the flatness on the main surface of the semiconductor substrate 1 can be improved. The isolation portion 3 is not limited to a grooved isolation portion but may be formed with a field insulating film formed, for example, according to a LOCOS 9local oxidization of silicon) method. The MIS's QL1, QL2 for load, MIS's Qd1, Qd2 for drive and MIS's Qt1, Qt2 for selection are, respectively, form in the active region L surrounded with the isolation portion.

The MIS's QL1, QL2 for load are first described. The MIS's QL1, QL2 for load are, respectively, made of pMIS and have a pair of p⁺-type semiconductor regions 4, 4 for source•drain, a gate insulating film 5 and a gate electrode 6a. The paired p-type semiconductor regions 4, 4 are formed by introducing, for example, boron into the n-well 2NW of the semiconductor substrate 1. In Embodiment 1, the paired p-type semiconductor regions 4, 4 of the MIS's QL1, QL2 for load are arranged to have an offset structure as set forth hereinbefore. More particularly, the end portions (i.e. channel side end portions) of the paired p-type semiconductor regions 4 toward the channel sides of the MIS's QL1, QL2 for load are arranged to be kept away (or shifted) toward a more distant direction from the end portion of the side face of a gate electrode 6a so as not to be superposed with the gate electrode 6a (see FIGS. 16, 18 and 20). More particularly, the end portions of the semiconductor regions for source•drain are kept away from the opposite ends at a bottom side of the gate electrode at which the intensity of an electric field is relatively high, under which the electric field intensity applied to the end portions of the semiconductor regions for source•drain can be mitigated, thereby suppressing or preventing passage of the GIDL current. In this way, the GIDL current can be reduced in a state of holding data in the MIS's QL1, QL2 for load. Accordingly, the leakage current in a data-holding state of the SRAM cell can be reduced, resulting in the reduction in consumption power of the semiconductor integrated circuit device as a whole. Because it is unnecessary to increase the impurity concentration of the source•drain of the MIS's QL1, QL2 for load constituted of pMIS, problems on the leakage current between the source•drain and the punch-through can be suppressed or prevented. Thus, the working reliability of the semiconductor integrated circuit device can be improved. At the upper portion of the paired p⁺-type semiconductor regions of the MIS's QL1, QL2 for load, there is formed a silicide film 7 made, for example, of cobalt silicide (CoS1) or the like. This enables the reduction of a contact resistance with a wiring, a parasitic capacitance and the like. It will be noted that the silicide film 7 may be made, for example, of tungsten silicide (WSi), nickel silicide (NiSi), titanium silicide (TiSi) or molybdenum silicide (MoSi).

The gate insulating film of the MIS's QL1, QL2 for load is made, for example of silicon oxide, with its thickness being, for example, at about 3 nm to 5 nm on calculation as a silicon dioxide film. The gate insulating film 5 may be constituted of a silicon oxide nitride (SiON) in place of the silicon oxide film. The silicon oxide nitride film is more effective in suppressing occurrence of an interface level in the film or reducing an electron trap in comparison with the silicon oxide film, so that the hot carrier durability of the gate insulating film 5 can be improved, thus leading to an improvement in dielectric strength. Moreover, the silicon oxide nitride film is more unlikely to permit an impurity to pass therethrough when compared with a silicon oxide film. When the gate insulating film 5 is formed of a silicon oxide nitride film, a variation in threshold voltage, which is ascribed to the diffusion of an impurity in a gate electrode material toward the semiconductor substrate can be suppressed. For the formation of the silicon oxide nitride, for example, it is sufficient to thermally treat the semiconductor substrate 1 in an atmosphere of a nitrogen-containing gas such as NO, NO₂or NH₃. Similar results may be obtained by forming a gate insulating film 5 made of silicon oxide on the surface of each of the p-well 2PW and n-well 2NW, after which the semiconductor substrate 1 is thermally treated in such a nitrogen-containing gas atmosphere as mentioned above thereby causing nitrogen to be segregated at the interface between the gate insulating film 5 and the semiconductor substrate 1.

Moreover, the gate insulating film 5 may be formed of a silicon nitride film or a composite insulating film made of a silicon oxide film and a silicon nitride film. When the gate insulating film 5 made of silicon oxide is formed in a thickness as thin as less than 5 nm, especially less than 3 nm, when calculated as silicon dioxide, the direct occurrence of a tunnel current and the lowering of dielectric strength caused by a stress by means of hot carriers are actualized. The silicon nitride film is higher in dielectric constant than a silicon oxide film, so that the film thickness determined by calculation as silicon dioxide can be made thinner than an actual film thickness. Accordingly, when the gate insulating film is constituted of a single silicon nitride film or a composite film thereof with a silicon oxide film, an effective film thickness can be made larger than a gate insulating film constituted of a silicon oxide film. Eventually, the occurrence of a tunnel leakage current and the lowering of the dielectric strength can be avoided.

The gate electrode 6a of the MIS's QL1, QL2 for load is so arranged as to have a so-called polyside structure where a silicide film 7 made, for example, of cobalt silicide is formed, for example, on a low resistance polysilicon film. The provision of the silicide film 7 on the top of the gate electrode 6 entails a significant lowering in resistance of the gate electrode 6a over the case where the silicide film 7 is not formed. In addition, the contact resistance with a wiring and a parasitic resistance can also be lowered. Accordingly, the working speed of SRAM can be improved. The silicide film 7 on the top of the gate electrode 6a is formed simultaneously with the step of forming the silicide film 7 on top of the paired p⁺-type semiconductor regions 4. It will be noted that the silicide film 7 on top of the gate electrode 6a can be formed, for example, of tungsten silicide (TiSi), nickel silicide (NISi), titanium silicide (TiSi), or molybdenum silicide (MoSi). The gate electrode 6a is formed at side faces thereof with a side wall (side wall insulating film) made, for example, of silicon oxide or silicon nitride.

This gate electrode 6a is not limited to such a polyside structure as set out hereinabove but various modifications are possible. For instance, there maybe used a so-called polymetal structure wherein a metal film such as tungsten (W), titanium (Ti) or molybdenum (Mo) is deposited on a polysilicon film via a barrier film made of tungsten nitride (WN), titanium nitride (TiN) or the like. In this case, the resistance of the gate electrode 6a can be significantly reduced in comparison with the case using the polyside structure. As will be described hereinafter, the gate electrode 6a is part of a wiring. More particularly, when the wiring is arranged as a polymetal structure, the resistance of the wiring can be remarkably reduced. Accordingly, it becomes possible to expect an improvement in working speed of the semiconductor integrated circuit device.

Further, such SiGe layers as mentioned above are superposed on the polysilicon film to provide the gate electrode 6a. In this case, the concentration of Ge should preferably be at a level of 40% or over because of the ease in setting a work function of the gate electrode 6a at a level between the work function (about 4.15 V) of n-type polysilicon and the work function (about 5.15 V) of p-type polysilicon. Where pMIS and nMIS are provided on the same semiconductor substrate, there is known a technique (i.e. a so-called dual gate structure) of separately introducing an impurity into gate electrodes of individual MIS's in order to prevent the lowering of threshold voltages of pMIS and nMIS without increasing an impurity concentration in the semiconductor substrate. However, this technique needs separate implantations of impurities, with the attendant problem that the number of fabrication steps increases. A film, into which separate impurities are introduced, is etched at one time, thus presenting the problem that a processing dimension is varied thereby worsening a processing dimensional accuracy of a gate electrode. In contrast, where a SiGe layer is used as a gate electrode, its work function can be set at a level between the work function of n-type polysilicon and the work function of p-type polysilicon, so that such a step of introducing separate impurities as mentioned above is unnecessitated. Thus, the process of manufacturing a semiconductor integrated circuit device having a CMIS-type SRAM cell can be simplified. The simplification of the manufacturing process enables one to reduce costs for the semiconductor integrated circuit device. In addition, the processing dimensional accuracy of the gate electrode can be improved. This makes it possible to improve the performance of the semiconductor integrated circuit device having the CMIS-type SRAM cell. The yield of the semiconductor integrated circuit device having the CMIS-type SRAM cell can be increased. Moreover, a polysilicon film is formed via the SiGe layer on a polysilicon film, followed by further formation of the silicide layer 7 on the uppermost polysilicon layer. More particularly, the uppermost polysilicon film is silicified (or is subjected to silicide process) to form the silicide film 7. In the case, aside from the effect obtained by use of the SiGe, effects of reducing a contact resistance, a parasitic capacitance and the like can also be obtained.

Next, MIS's Qd1, Qd2 for drive are described. MIS's Qd1, Qd2 for drive are, respectively, made of nMIS as set forth hereinbefore, and have a pair of n⁺-type semiconductor regions 9a, 9b for source•drain, a gate insulating film 5 and a gate electrode 6b. The pair of n⁺-type semiconductor regions 9a, 9b are formed, for example, by introducing phosphorus or arsenic into the p-well 2PW of the semiconductor substrate 1. In this Embodiment 1, the pair of n⁺-type semiconductor regions 9a, 9b of the MIS's Qd1, Qd2 for drive are arranged as an offset structure. More particularly, in the pair of n⁺-type semiconductor regions 9a, 9b, the channel side end portion is kept away (or shifted) by a given length toward a more distant direction from the end portion of the side face of the gate electrode 6b so as not to be superposed with the gate electrode 6b (see FIGS. 15, 19 and 20). In doing so, the GIDL current in a data-holding state can be reduced in the MIS's QL1, QL2 for drive. This leads to the reduction in leakage current in a data-holding state of the SRAM cell MC, resulting in the reduction in consumption power of the semiconductor integrated circuit device as a whole. The silicide film 7 is formed on top of the pair of n⁺-type semiconductor regions 9a, 9b of the MIS's Qd1, Qd2 for drive. The formation enables the contact resistance with a wiring and the parasitic capacitance to be reduced.

The gate insulating film 5 and the gate electrode 6b of the MIS's Qd1, Qd2 for drive are, respectively, for simultaneously with the formation of the gate insulating film 5 and the gate electrode 6a of the MIS's QL1, QL2 for load. The materials and structures therefor are same as the gate insulating film 5 and the gate electrode 6a of the MIS's QL1, QL2 for load and are not specifically described herein.

It will be noted that the gate electrodes 6a, 6b of the MIS's QL1, QL2 for load and the MIS's Qd1, Qd2 for load are, respectively, formed as part of wirings 6, 6 substantially in the form of Y as viewed on a plane. More particularly, one wiring 6 includes a wiring portion linearly connecting the gate electrodes 6a, 6b of the MIS QL1 for load and the MIS Qd1 for drive and a wiring portion extending in an inclined direction relative to the first-mentioned wiring and electrically connecting to one n-type semiconductor regions 9b of the MIS Qd2 for drive. Other wiring 6 serving as a counterpart to the first-mentioned one has a wiring portion linearly connecting the gate electrodes 6a, 6b of the MIS QL2 for load and the MIS Qd2 for drive and a wiring portion extending in an inclined direction relative to the first-mentioned wiring and electrically connecting to one of the p-type semiconductor regions 4 of the MIS QL1 for drive. It is to be noted that the material and structure for the wiring 6 are same as those of the gate electrodes 6a, 6b.

Although not specifically limited to, an instance of sizes and impurity concentrations at individual portions of the MIS's QL1, QL2 for load and the MIS's Qd1, Qd2 for load is shown in FIG. 20 for reference. The gate length Lg1 is, for example, at approximately 0.16 μm, and the width L of the side wall 8 is, for example, at approximately 0.7 μm. The depths of the p⁺-type semiconductor regions 4 and the n⁺-type semiconductor regions 9a, 9b (i.e. a length covering from the main surface of the semiconductor substrate 1 to a depletion layer of the pn junction) are, for example, at approximately 200 nm, respectively. The impurity concentration in a channel region CH is, for example, at approximately 2×10¹⁸/cm³. The impurity concentration in a region A at the channel side end portion of the p⁺-type semiconductor regions 4 and the n⁺-type semiconductor regions 9a, 9b is, for example, at approximately 5×10¹⁸/cm³, and the impurity concentration in a region B (which is generally a region where a low impurity concentration region and a high impurity concentration region are superposed) is, for example, at approximately 1×10²⁰/cm³. An impurity concentration in a region C (a region consisting of a semiconductor region of a high impurity concentration) lower than the region B is, for example, at approximately 1×10¹⁸/cm³.

Next, the MIS's Qt1, Qt2 for selection is now described. The MIS's Qt1, Qt2 for selection are, respectively, comprised of nMIS as stated before and have a pair of n-type semiconductor regions 10a, 10b for source•drain, a gate insulating film 5 and a gate electrode 11. In this case, there is shown an instance where the pair of n-type semiconductor regions 10a, 10b of the MIS's Qt1, Qt2 for selection have a non-offset structure as shown in FIG. 11. More particularly, the MIS's Qt1, Qt2 for selection have the same structure as ordinary MIS. Accordingly, the reduction of consumption power becomes possible without delaying such read out and write times.

The pair of semiconductor regions 10a, 10b, respectively, have n⁺-type semiconductor regions 9b, 9c of a relatively high impurity concentration and n⁻-type semiconductor regions 9d, 9d of a relatively low impurity concentration provided at a channel side end portion of the regions 9b, 9c. The n⁺-type semiconductor regions 9b, 9c and the n⁻-type semiconductor regions 9d, 9d are all formed by introducing, for example, phosphorus or arsenic into the p-well 1PW. The n -type semiconductor regions 9d, 9d is a region mainly serving as a semiconductor region for DD. In the n-type semiconductor regions 9d, 9d, the ends at the channel sides of the MIS's Qt1, Qt2 for selection may be so arranged as to be partially superposed with the gate electrode 11 by a given length, or may be substantially coincident with opposite ends of the gate electrode 11 (see FIGS. 16, 23 and 24). On the other hand, the n⁺-type semiconductor regions 9b, 9c have channel side end portions which are formed as being kept away from opposite ends of the gate electrode substantially by a width of the side wall 8. The silicide film 7 is formed on top of the n⁺-type semiconductor regions 9b, 9c. In this way, the contact resistance with a wiring and a parasitic capacitance can be reduced.

The gate insulating film 5 and the gate electrode 11 of the MIS's Qt1, Qt2 for selection are formed simultaneously with the formation of the gate insulating film 5 and the gate electrode 6a of the MIS's QL1, QL2 for load, and the constituting materials and structures are same as those of the gate insulating film 5 and the gate electrode 6a of the MIS's QL1, QL2 for load and are not specifically described again. In this connection, however, gate electrodes 11, 11 of MIS's Qt1, Qt2 for selection are, respectively, formed of part of the same word line WL. The word line WL is formed in a band-shaped pattern extending substantially linearly in a transverse direction in FIG. 14. The word line WL is integrally formed and extended from one end to the other of the SRAM cell-forming region. When this word line WL is formed as the polyside structure, the wiring resistance can be reduced, thereby enabling the working speed of SRAM to be increased. When the word line WL is arranged as the polymetal structure, the wiring resistance can be further reduced, resulting in a further increase in the working speed of SRAM. Moreover, the limit of the line length of the word line WL can be increased, so that a degree of integration of elements can be increased, thus making it possible to increase a memory capacity of SRAM. It will be noted that the width of the word line WL is, for example, at approximately 0.25 μm.

Next, in case where there exists a logic circuit in the peripheral circuit of SRAM or within the same semiconductor chip, nMIS Qn and pMIS Qp constituting the peripheral circuit and the logic circuit are described mainly with reference to FIGS. 17 and 21 to 24. nMIS Qn and pMIS Qp, respectively, have a non-offset structure as set out hereinbefore. Accordingly, a satisfactory working speed is ensured with respect to the peripheral circuit and the logic circuit, enabling the working speed of the semiconductor integrated circuit device to be ensured.

NMIS Qn has a pair of n-type semiconductor regions 12, 12 for source•drain, a gate insulating film 5 and a gate electrode 13. The pair of n-type semiconductor regions 12, 12, respectively, have n³¹ -type semiconductor regions 12a, 12a of a relatively low impurity concentration provided at the channel sides of nMIS Qn and n⁺-type semiconductor regions 12b, 12b of a relatively high impurity concentration connected thereto. The n⁻-type semiconductor region 12a and the n⁺-type semiconductor region 12b are, respectively, formed by introducing, for example, phosphorus or arsenic into p-well 2PW.

The n⁻-type semiconductor region 12a is a region mainly functioning as the semiconductor region for LDD and is arranged such that the end portion at the channel side thereof is partially superposed with the gate electrode 13 by a given length or is substantially coincident with the opposite ends of the gate electrode 13 (see FIGS. 17, 23 and 24). On the other hand, the n⁺-type semiconductor region 12b is formed such that the end portions at the channel sides thereof are kept away from the opposite ends of the gate electrode 13 substantially by a width of the side wall 8. The silicide film 7 is formed on top of the n⁺-type semiconductor region 12b. In this arrangement, the contact resistance with a wiring and the parasitic capacitance or the like can be reduced.

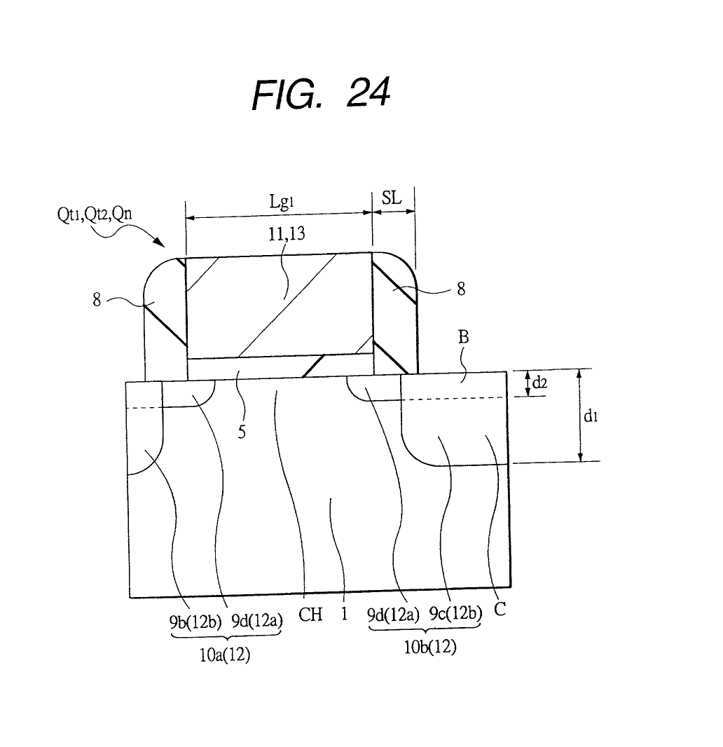

Although not limited specifically, an instance of the sizes and impurity concentrations of individual parts of MIS's Qt1, Qt2 for selection and nMIS Qn is described in FIG. 24 for reference. The gate length Lg1, the width of the side wall 8, the depths of the n⁺-type semiconductor regions 9b, 9c, 12b for source•drain (i.e. a length of from the main surface of the semiconductor substrate 1 to the depletion layer of the pn junction) d1 and the impurity concentration of the channel region CH are, respectively, same as illustrated with reference to FIG. 20. The depths of the n⁻-type semiconductor regions 9d, 12a (i.e. a length of from the main surface of the semiconductor substrate 1 to the depletion layer of the pn junction) d2 is, for example, at approximately 50 nm. The impurity concentration in the n⁻-type semiconductor regions 9d, 12a is, for example, at approximately 1×10¹⁹/cm³. The impurity concentration in the region B at the side of the main surface of the pair of semiconductor regions 10a, 10b or 12 for source•drain (i.e. usually a region where a low impurity concentration semiconductor region and a high impurity concentration semiconductor region are superposed) is, for example, at approximately 1×10²⁰/cm³, and an impurity concentration in the region C lower than the region B (i.e. a region consisting of a semiconductor region of a high impurity concentration) is, for example, at approximately 1×10¹⁸/cm³.

On the other hand, pMIS Qp has a pair of n-type semiconductor regions 14, 14 for source•drain, a gate insulating film 5 and a gate electrode 15. The pair of n-type semiconductor regions 14, 14 have, respectively, p⁻-type semiconductor regions 14a, 14a of a relative low impurity concentration and p⁺-type semiconductor regions 14b, 14b of a relatively high impurity concentration connected thereto. The p⁻-type semiconductor region 14a and p⁺-type semiconductor regions 14b are, respectively, formed by introducing, for example, boron into the n-well 2NW. The p⁻-type semiconductor regions 14a are ones functioning mainly as a semiconductor region for LDD, and the end portions at the channel sides thereof may be superposed partially with the gate electrode 15 by a given length, or may be substantially coincident with the opposite ends of the gate electrode 15 (see FIGS. 17, 21 and 22). On the other hand, the p⁺-type semiconductor regions 14b are so formed that the end portions at the channel sides thereof are kept away from the opposite ends of the gate electrode 15 substantially by a width of the side wall 8. The silicide film 7 is formed on top of the p⁺-type semiconductor region 14b. Thus, the contact resistance with a wiring and the parasitic capacitance can be reduced. It will be noted that the gate insulating film 5 and the gate electrodes 13, 15 of the nMIS Qn and pMIS Qp are formed simultaneously with the formation of the MIS's QL1, QL2 for load, and the materials and structures thereof are same as those of the gate insulating film 5 and the gate electrode 6a of the MIS's QL1, QL2 for load and are not specifically described herein.

Although not limited specifically, an instance of the sizes and impurity concentrations of individual parts of pMIS Qp is described in FIG. 22 for reference. The gate length Lg1, the width of the side wall 8, the depth of the p⁺-type semiconductor regions 14b for source•drain (i.e. a length of from the main surface of the semiconductor substrate 1 to the depletion layer of the pn junction) d1, the impurity concentration in the channel region CH, and the impurity concentrations in the regions B, C of the semiconductor region 14 are, respectively, same as illustrated with reference to FIG. 20. The depth of the p⁻-type semiconductor regions 14a (i.e. a length of from the main surface of the semiconductor substrate 1 to the depletion layer of the pn junction) d2 is, for example, at approximately 100 nm. The impurity concentration of the p⁻-type semiconductor regions 14a is, for example, at 1×10¹⁹/cm³.

An interlayer insulating film 16 made, for example, of silicon oxide is deposited on the main surface of the semiconductor substrate 1. Contact holes 17 are made in the interlayer insulating film 16. Part of each of the n⁻-type semiconductor region 9b and the wiring 6 is exposed from a contact hole 17a among the contact holes 17 (see FIGS. 14 and 15). Part of each of the n⁺-type semiconductor region 4 and the wiring 6 is exposed from a contact hole 17b of the SRAM cell MC (see FIG. 14). A plug 18 is buried in the contact hole 17. The plug 18 is made, for example, of tungsten or the like. The plugs 18 are electrically connected to the semiconductor region for source•drain and the gate electrode of individual MIS's, respectively. The plug 18 buried in the contact hole 17a electrically connects the n⁺-type semiconductor region 9b and the wiring 6 therewith. The plug 18 buried in the contact hole 17b electrically connect the p⁺-type semiconductor region 4 with the wiring 6 therewith. A first-layer wiring 19 is formed on the interlayer insulating film 16. The first-layer wiring 19 is made, for example, of a titanium film built up on a titanium nitride layer via an aluminium-silicon-copper alloy film and is electrically connected via the plug 18 to the semiconductor region for source•drain and the gate electrode of individual MIS's. The plug 18 inside the contact hole 17a is electrically connected to the plug 18 inside the contact hole 17c via a first-layer wiring 19a. The plug 18 inside the contact hole 17b is electrically connected to the plug 18 inside a contact hole 17d via the first-layer wiring 19.

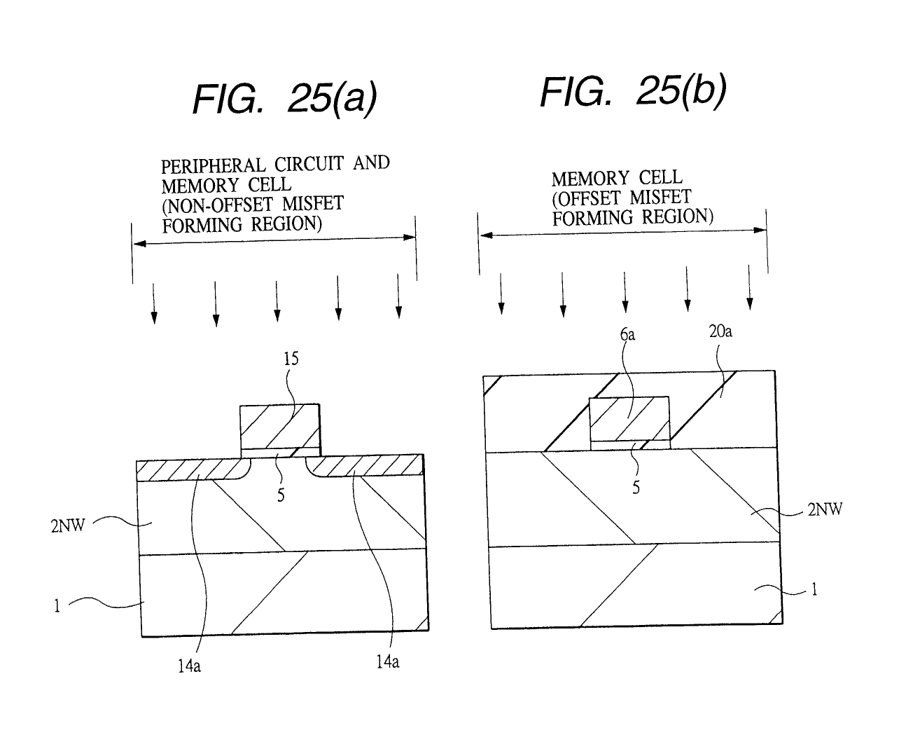

Next, an instance of the manufacture of the semiconductor integrated circuit device according to Embodiment 1 is described with reference to FIGS. 25(a), 25(b) to 28 (a), 28(b). In FIGS. 25(a) to 28(b), a pMIS portion alone is described for convenience's sake, which is true of the manufacture of nMIS. In FIGS. 25(a) to FIG. 28(b), FIGS. 25(a). 26(a), 27(a) and 28(a), respectively, show a pMIS-forming region having a non-offset structure of a logic circuit where there exist logic circuits in an SRAM cell and a peripheral circuit and in the same semiconductor chip, and FIGS. 25(b). 26(b), 27(b) and 28(b), respectively, show a pMIS-forming region having an offset structure of an SRAM cell.

As shown in FIGS. 25(a) and 25(b), after formation of the n-well 2NW on the semiconductor substrate 1, the gate insulating film 5 is formed, on which gate electrodes 15, 6a are, respectively, formed. It will be noted that the gate electrodes 15, 6a are formed by depositing a conductive film for gate electrode formation and patterning the film in the same patterning step. As stated hereinbefore, the conductive film for gate electrode formation may be formed by successively depositing a silicon film, an SiGe layer and a silicon film. At this stage, any silicide film is not formed on the gate electrodes 15, 6a. Subsequently, a photoresist pattern 20a is formed on the main surface of the semiconductor substrate 1. The photoresist pattern 20a is so formed as to cover the pMIS-forming region having an offset structure and expose the pMIS-forming region having a non-offset structure. There after, the semiconductor substrate 1 is introduced, for example, with boron by an ion implantation method or the like, so that a p⁻-type semiconductor region 14a having a low impurity concentration is formed in the pMIS-forming region having the non-offset structure self-alignedly with the gate electrode 15.

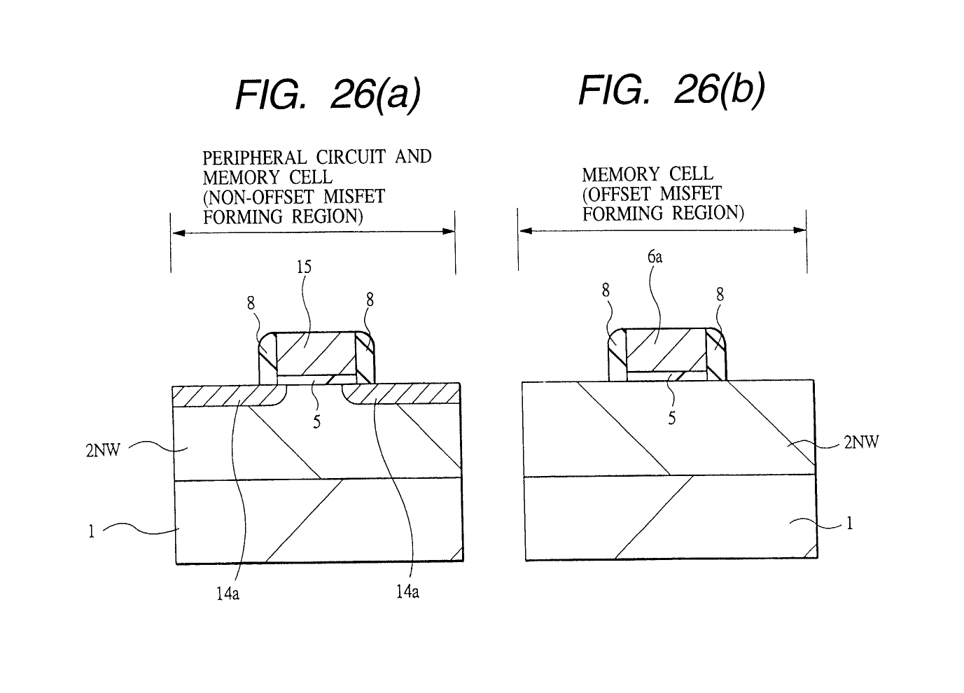

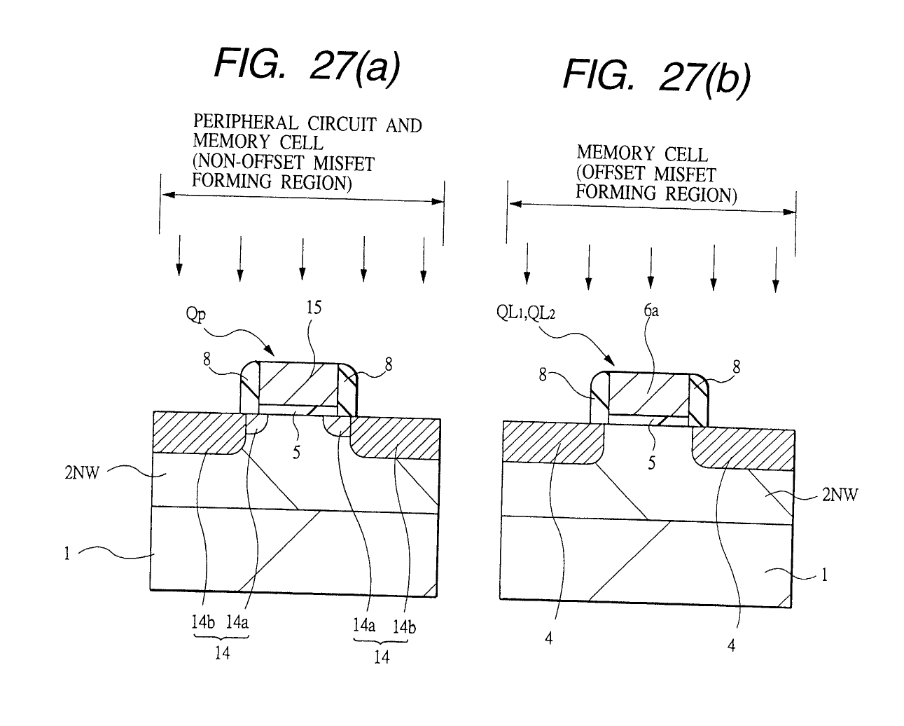

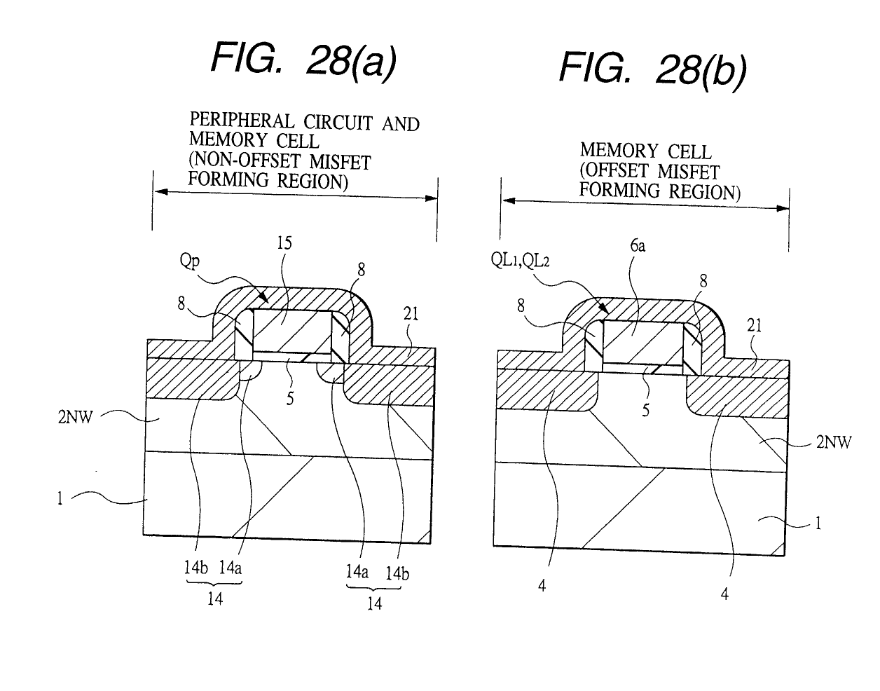

Subsequently, after removal of the photoresist pattern 20a, an insulating film made, for example, of silicon oxide is deposited over the main surface of the semiconductor substrate 1 by a CVD (chemical vapor deposition) method or the like, followed by etching back such as by an anisotropic dry etching technique to form side walls 8 on the side surfaces of the gate electrodes 6a, 15 as is particularly shown in FIGS. 26(a) and 26(b). Thereafter, as shown in FIGS. 27(a), 27(b), boron is, for example, introduced into the semiconductor substrate 1 by an ion implantation method or the like to form p⁺-type semiconductor regions 14b, 4 of a high impurity concentration in the pMIS-forming region having the non-offset structure and the pMIS-forming region having the offset structure of the SRAM cell self-alignedly relative to the gate electrodes 15, 6a and the side walls 8, respectively. With the pMIS (MIS's QL1, L2 for load) having an offset structure, the channel side ends of the p⁺-type semiconductor region 4 is formed as kept away from the opposite ends of the gate electrode 6a by a given length. In this way, pMIS Qp having the non-offset structure and pMIS having the offset structure (MIS QL1, L2 for load) are, respectively, formed. As shown in FIGS. 28(a) and 28(b), after deposition of a conductive film 21 made, for example of cobalt, nickel, titanium or the like on the main surface of the semiconductor substrate 1 by a sputtering method or the like, the substrate is subjected to thermal treatment in an atmosphere of an inert gas (i.e. silicification) thereby self-alignedly forming the silicide film 7 such as cobalt silicide at an interface of contact of the conductive film 21, the semiconductor substrate 1 and the gate electrodes 6a, 15 (silicide process). It will be noted that where the gate electrodes 15, 6a are formed of a multi-layered film including a silicon film, a SiGe layer and a silicon film, at least the silicon film on the SiGe layer may be silicified to form the silicide film 7.

### Embodiment 2

Embodiment 2 illustrates a modification of the countermeasure against the GIDL current in Embodiment 1, and an instance where MIS source•drain having an offset structure has a low impurity concentration semiconductor region and a high impurity concentration semiconductor region is described.

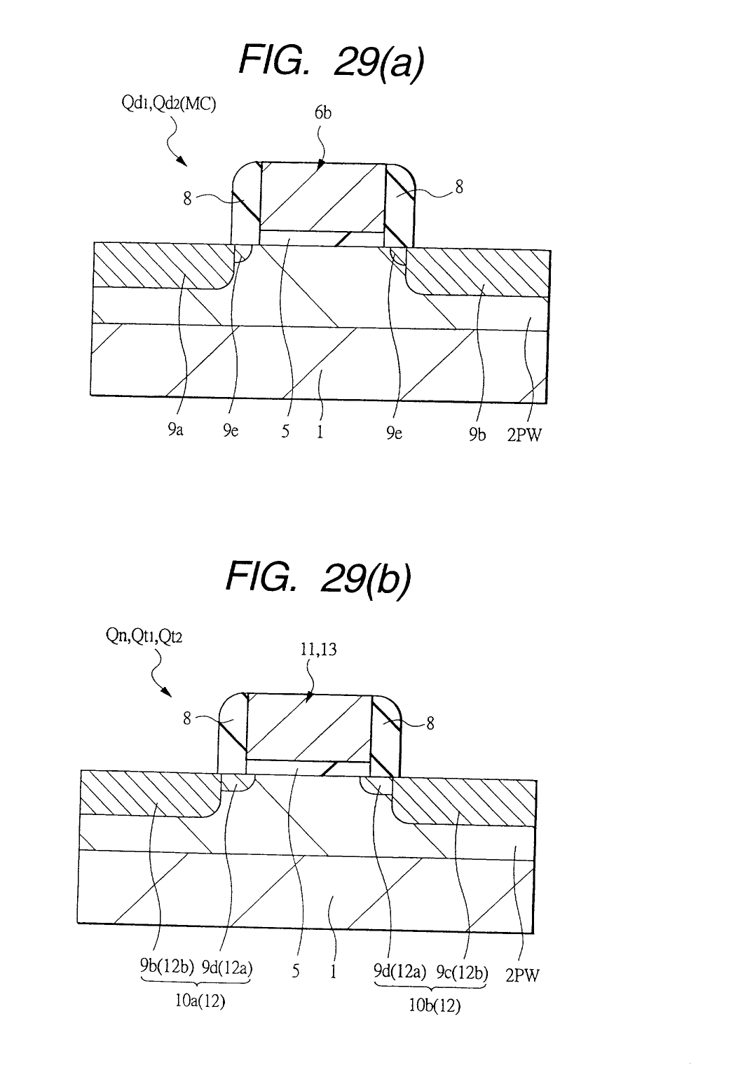

FIG. 29 (a) shows such MIS's Qd1, Qd2 for drive as set forth hereinabove for use as MIS having an offset structure in Embodiment 2, and FIG. 29(b) shows such MIS's Qt1, Qt2 for selection as set forth hereinabove for use as MIS having a non-offset structure. In this embodiment, nMIS is illustrated, and pMIS may be likewise arranged to have such structures as nMIS subjected to a measure against the GIDL current in a manner as set out in this embodiment and also as nMIS not subjected to the measure against GIDL.

As shown in FIG. 29(a), a pair of semiconductor regions for source•drain of MIS's Qd1, Qd2 for drive have an n-type semiconductor region 9e located at the channel side, and an n⁺-type semiconductor region 9a connected thereto. The n-type semiconductor region 9e is lower in impurity concentration than the n⁺-type semiconductor region 9a, and its impurity concentration is set at such a level as the impurity concentration in an n⁻-type semiconductor region 9d of nMIS Qn having a non-offset structure of FIG. 29(b) and an n⁻-type semiconductor region 12a of MIS's Qt1 Qt2 for selection. The end portion at the channel side of the n⁻-type semiconductor region 9e is arranged in a direction kept away from the opposite end portions of the gate electrode 6b by a given length for the measure against the GIDL current (offset structure). It will be noted that nMIS Qn and MIS's Qt1, Qt2 for selection in FIG. 29(b) have the same structures as described hereinbefore, respectively, which are not described again.

According to Embodiment 2 of the invention, the following effects are obtained, aside from those effects obtained in the Embodiment 1

(1) Because the parasitic resistance in the channel of MIS having an offset structure of the SRAM cell MC can be reduced, a drain current can be increased. This contributes to improved speeds of read out and write operations of the SRAM cell MC, so that the working speed of the semiconductor integrated circuit device having a plurality of SRAM cells MC can be increased.

(2) The semiconductor region having a low impurity concentration is provided at the source•drain of MIS having an offset structure of SRAM cell MC, so that the hot electron effect can be mitigated, thereby making it possible to improve working reliability of the MIS.

### Embodiment 3

Embodiment 3 is another modification of Embodiment 1. As a measure against the GIDL current, there is described the case where an impurity concentration in a semiconductor region of a low impurity concentration for source•drain of MIS is made lower than an impurity concentration in a semiconductor region of a low impurity concentration for source•drain of MIS not requiring any measure against the GIDL current.

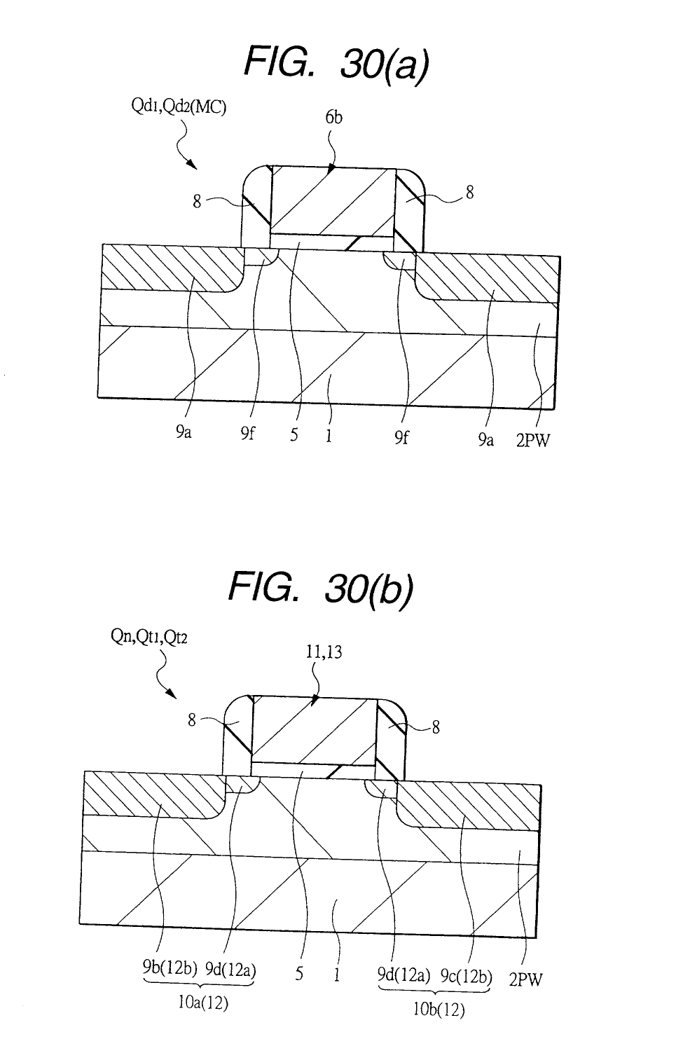

FIG. 30(a) shows such MIS's Qd1, Qd2 for drive as described before as MIS used for the measure against the GIDL current in Embodiment 3, and FIG. 30(b) shows MIS Qn and MIS's Qt1, Qt2 for selection, which are MIS's using the same drive source voltage as the MIS improved in GIDL and which do not take any measure against the GIDL current. It will be noted that although nMIS is illustrated in this embodiment, pMIS may have structures like nMIS improved in GIDL and set out herein and nMIS not improved in or taking no measure against GIDL.

As shown in FIG. 30(a), a pair of semiconductor regions for source•drain of MIS's Qd1, Qd2 for drive have an n⁻-type semiconductor region 9f provided at a channel side and an n⁺-type semiconductor region 9a connected thereto. The n⁻-type semiconductor region 9f is so arranged that the impurity concentration thereof is lower than the impurity concentration of the n⁺-type semiconductor region 9a and is also lower than the impurity concentrations of the n⁻-type semiconductor region 9d of nMIS Qn and the n⁻-type semiconductor regions 12a of the MIS's Qt1, Qt2 for selection, both having the non-offset structure shown in FIG. 30(b). The channel side end portions of the n-type semiconductor region 9f in the MIS's Qd1, Qd2 needing the measure against the GIDL current are formed so as to be partially superposed with the gate electrode 6b or located substantially at the same positions as the opposite ends of the gate electrode. More particularly, the non-offset structure is established. In this connection, however, since the impurity concentration of the n⁻type semiconductor regions 9f is made lower than those impurity concentrations of the n⁻-type semiconductor region 9d of nMIS Qn and the n⁻-type semiconductor regions 12a of the MIS's Qt1, Qt2, the GIDL current can be reduced in a data-holding state (stand-by state) of SRAM cell MC compared with the case where such a structure as used in this embodiment is not used. It will be noted that the nMIS Qn and MIS's Qt1, Qt2 shown in FIG. 30(b), respectively, have the same structures as described hereinbefore and are not described herein.

In Embodiment 3 of the invention, the following effects can be achieved.

(1) Because the source•drain structure is formed as a non-offset structure while taking a measure against the GIDL current with respect to MIS of SRAM cell MC, the GIDL current in a data-holding state of the SRAM cell MC can be suppressed, thereby increasing a drain current at MIS of the SRAM cell MC to improve the speeds of read-out and write operations while reducing consumption power.

(2) The provision of the semiconductor region of a low impurity concentration in MIS of the SRAM cell MC enables the hot electron effect of the MIS of the SRAM cell MC to be mitigated, thereby ensuring an improvement in working reliability of the MIS.

### Embodiment 4

Embodiment 4 illustrates a modification of MIS having an offset structure wherein for improving GIDL, the gate insulating film of the MIS is made relatively thick.

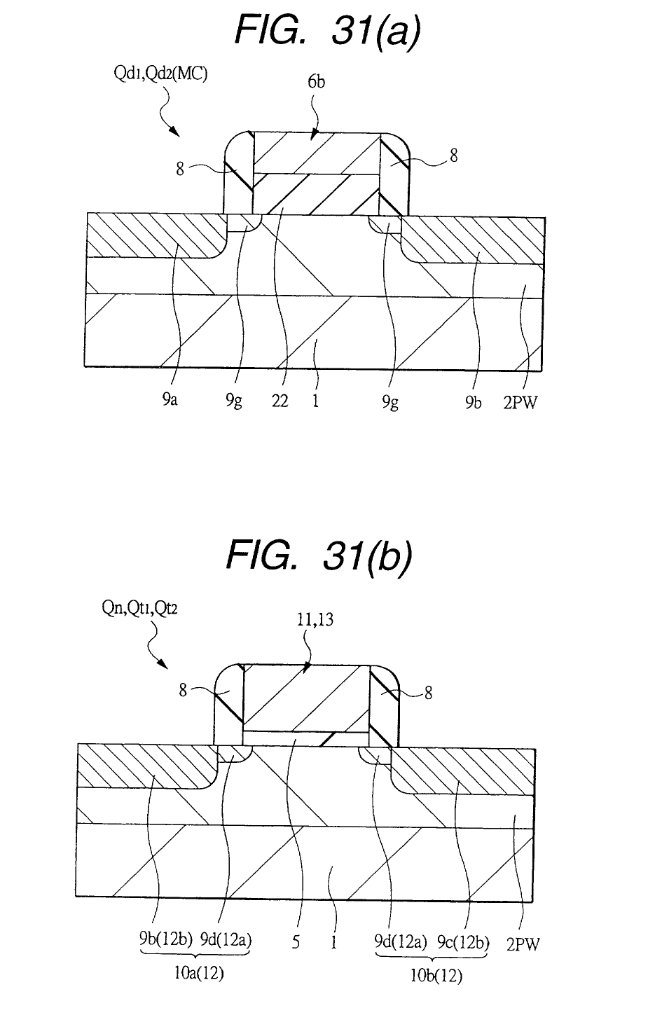

FIG. 31(a) shows such MIS's Qd1, Qd2 for drive as described hereinabove as MIS for improving GIDL, and FIG. 31(b) shows nMIS Qn and MIS's Qt1, Qt2 for selection, which are MIS's using the same drive source voltage as the MIS's improved in GIDL, and in which any measure against the GIDL current is not taken. It will be noted that in this embodiment, nMIS is illustrated and pMIS may have similar structures as nMIS subjected to the measure against the GIDL current and nMIS not subjected to the measure against the GIDL.

As shown in FIG. 31(a), a pair of semiconductor regions for source•drain of the MIS's Qd1, Qd2 for drive have an n⁻-type semiconductor region 9g provided at a channel side and an n⁺-type semiconductor region 9a connected thereto. The channel side end portions of the n ⁻-type semiconductor region 9g are arranged so as to be substantially coincident with the opposite ends of the gate electrode 6b or partially superposed with the gate electrode 6b (non-offset structure). The n⁻-type semiconductor region 9g is so arranged that the impurity concentration thereof is lower than the impurity concentration of the n⁺-type semiconductor region 9a and is substantially equal to the impurity concentrations of the n⁻-type semiconductor region 9d of nMIS Qn and the n⁻-type semiconductor regions 12a of the MIS's Qt1, Qt2 for selection of FIG. 31(b). More particularly, the structure of the pair of semiconductor regions for source•drain of the MIS's Qd1, Qd2 for drive is same as the structure of the pair of semiconductor regions for source•drain of the MIS's Qt1, Qt2 for selection.

For the improvement in GIDL, a gate insulating film 22 of the MIS's Qd1, Qd2 for drive is made thicker (when calculated as silicon dioxide film) than the gate insulating film 5 of the MIS's Qt1, Qt2 for selection. This serves to mitigate an electric field applied to the side of the semiconductor substrate 1, so that the GIDL current in a data-holding state of the SRAM cell MC can be reduced. The arrangement of this Embodiment 4 may be used in combination with any of those arrangements of Embodiments 1 to 3. In the case, similar effects are obtained. It will be noted that the structures of nMIS Qn and MIS's Qt1, Qt2 for selection of FIG. 31(b) are same as those described hereinbefore and are not described herein.

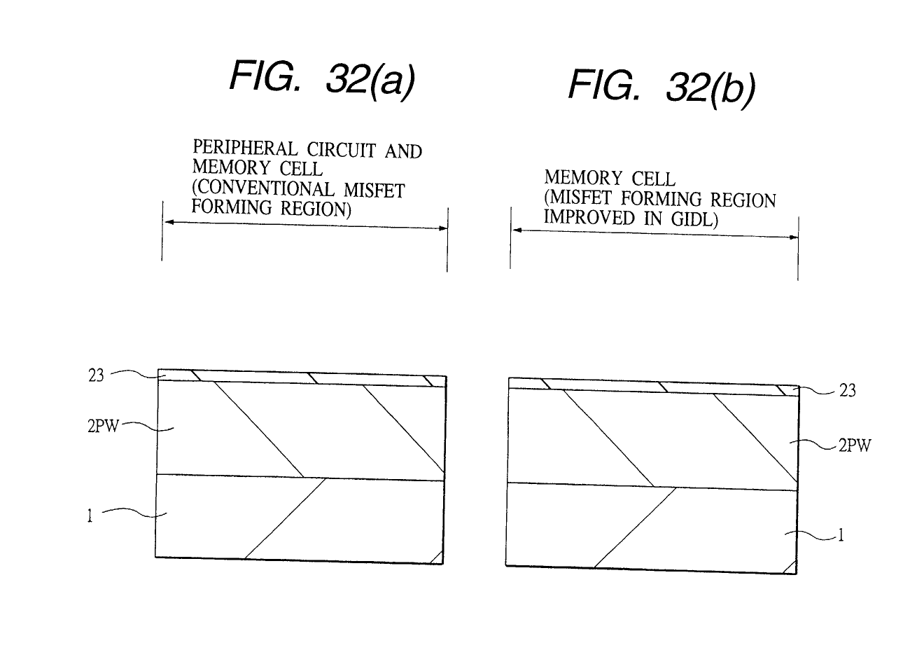

An example of a method of manufacturing a semiconductor integrated circuit device having such SRAM as stated above is described with reference to 32(a) to 35(b). FIGS. 32(a), 33(a), 34(a) and 35(a), respectively, show a MIS-forming region for an improvement in GIDL in Embodiment 4, and FIGS. 32(b), 33(b), 34(b) and 35(b), respectively, show a MIS-forming region whose drive source voltage is same as that of the MIS improved in GIDL and is not improved in GIDL or subjected to the measure against a GIDL current.

As shown in FIGS. 32(a) and 32(b), a gate insulating film 23 is formed on the main surface of a semiconductor substrate 1 by a thermal oxidation method or the like. At this stage, the gate insulating film 23 is formed over both a MIS-forming region to be improved in GIDL and a MIS-forming region free of any measure against GIDL current.

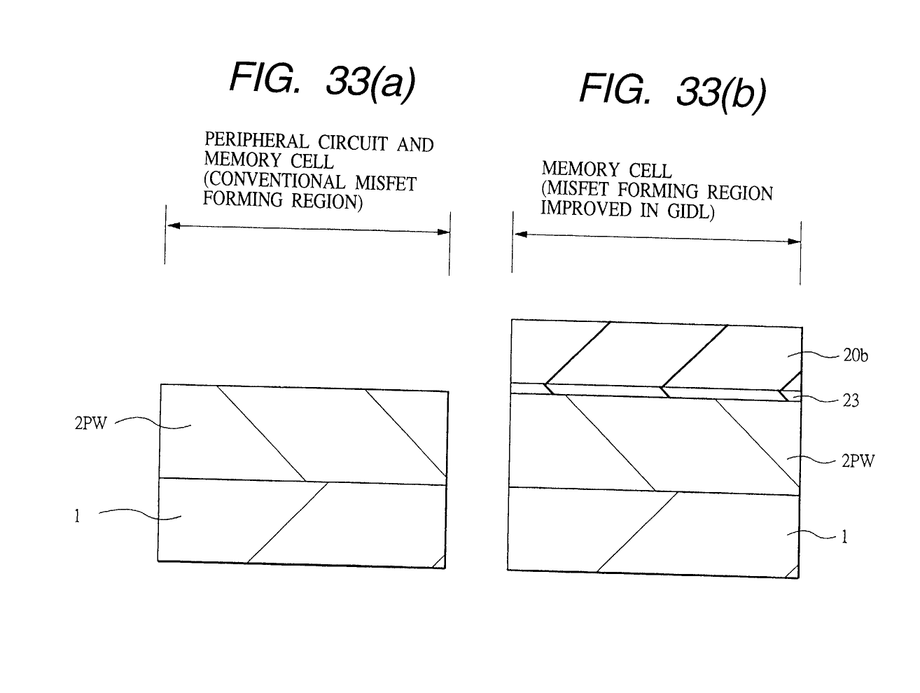

Subsequently, as shown in FIGS. 33(a) and 33(b), after formation of photoresist pattern 20b so that the MIS-forming region to be improved in GIDL is covered therewith whereas the MIS-forming region not to be improved in GIDL is exposed, the gate insulating film 23 is removed at a portion where exposed by etching with an etchant such as hydrofluoric acid (HF) or the like.

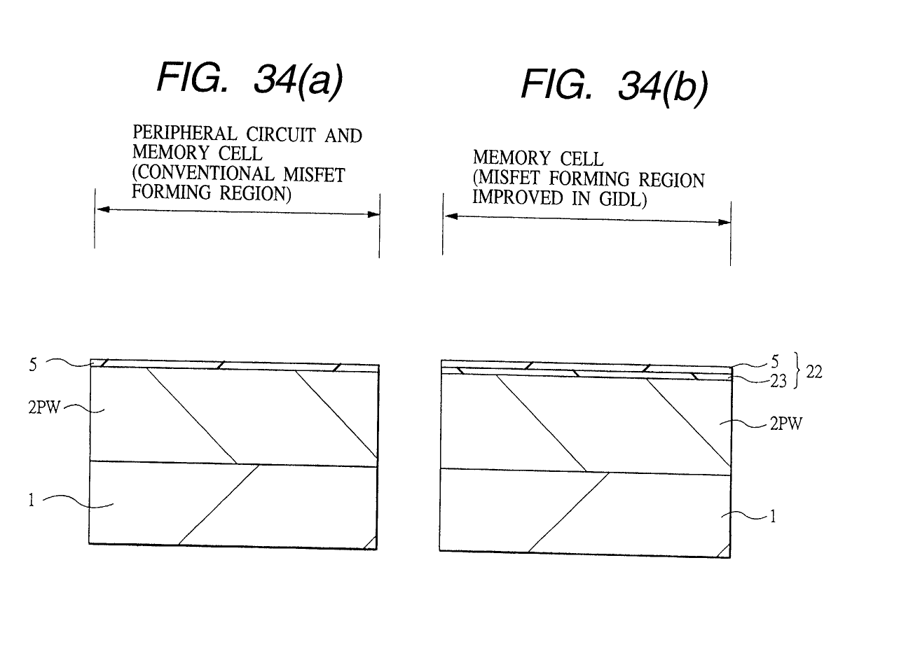

After removal of the photoresist pattern 20b, the semiconductor substrate 1 is again subjected to thermal oxidation treatment, thereby forming a multi-layered film of the insulating films 23, 5 (i.e. a gate insulating film 22) on the MIS-forming region to be improved in GIDL and a gate insulating film 5 on the MIS-forming region not taking any measure against the GIDL current as is particularly shown in FIGS. 34(a) and 34(b). In this way, the relatively thick gate insulating film 22 is formed on the MIS-forming region to be improved in GIDL.

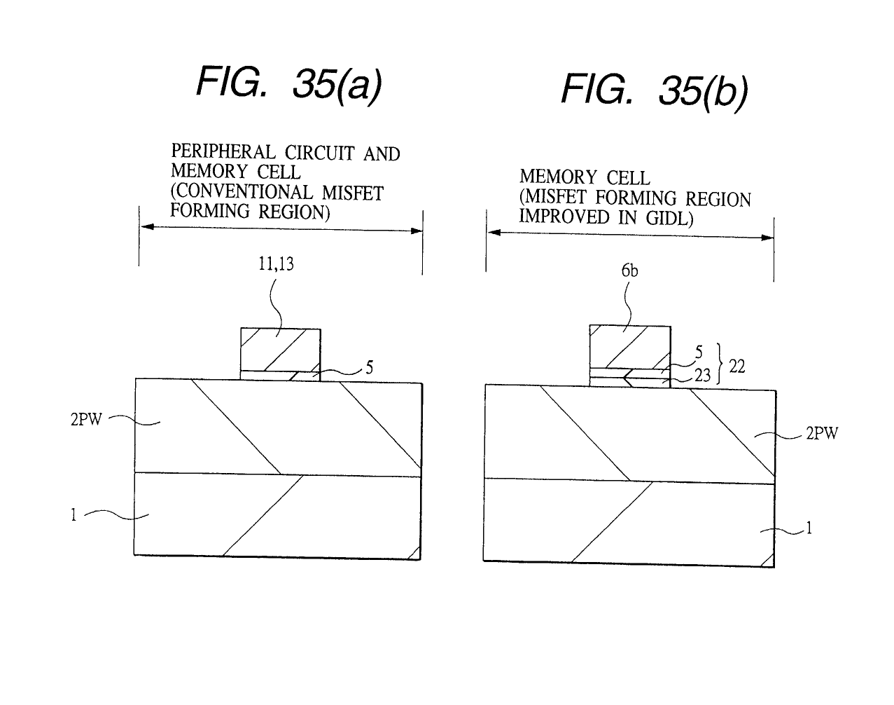

Next, after deposition of a conductive film for forming a gate electrode on the gate insulating films 5, 22, the conductive film is patterned according to ordinary lithographic and dry etching techniques to form gate electrodes 6b, 11, 13, respectively, as shown in FIGS. 35(a) and 35(b). At this stage, such a silicide film set forth before is not formed on the gate electrodes 6b, 11, 13.

Subsequently, using the gate electrodes 6b, 11, 13 as a mask, phosphorus or arsenic is, for example, introduced, thereby forming n⁻-type semiconductor regions 9b, 9g, 12b at the same step self-alignedly relative to the gate electrodes 6b, 11, 13. The n⁻-type semiconductor regions 9b, 9g, 12b, respectively, have anon-offset structure.

Thereafter, like Embodiment 1, a side wall 8 is formed side faces of the gate electrodes 6b, 11, 13, after which using the gate electrodes 6b, 11, 13 and the side walls 8 as a mask, phosphorus or arsenic is, for example, introduced, thereby forming n⁺-type semiconductor regions 9a, 9b, 12b at the same step self-alignedly relative to the gate electrodes 6b, 11, 13. Subsequent steps are similar to those of Embodiment 1 and are not described herein.

In the manufacturing steps of the semiconductor integrated circuit device having SRAM, gate insulating films having different thicknesses may be formed within the same semiconductor substrate. For instance, the gate insulating film of MIS needing a relatively high-speed operation may be, in some case, made thinner than a gate insulating film of MIS needing a relatively high dielectric strength. When the process of Embodiment 4 is applied to the process of the above case, a semiconductor integrated circuit device having SRAM can be manufactured without increasing the number of processes.

In Embodiment 4 of the invention, the following effects can be obtained.

(1) While taking a measure against the GIDL current with respect to MIS's of the SRAM cell MC, the source•drain structure is arranged as such a non-offset structure as ordinary MIS other than the SRAM cell MC. Eventually, the speeds of read-out and write operations can be increased while reducing consumption power by suppressing the GIDL current in a data-holding state of the SRAM cell MC.

(2) Because semiconductor regions having a low impurity concentration are provided in the MIS's of the SRAM cell MC, the hot electron effect of the MIS of the SRAM cell MC can be mitigated, like Embodiment 2, thus making it possible to improve the working reliability of the MIS.

(3) The source•drain regions of the MIS of the SRAM cell MC subjected to the measure against the GIDL current can be formed along with the formation of the source•drain regions of the MIS not subjected to the measure against the GIDL current.

(4) By virtue of (3) above, the developing or manufacturing time of the semiconductor integrated circuit device having SRAM can be shortened.

(5) By virtue of (3) above, the manufacturing costs of the semiconductor integrated circuit device having SRAM can be reduced.

The invention has been described based on the embodiments of the invention, which should not be construed as limiting the invention thereto. Various variations and modifications maybe possible without departing from the spirit of the invention.

For instance, such an SOI substrate may be used as a semiconductor substrate. More particularly, the semiconductor substrate may have a structure wherein a semiconductor layer for element formation made of single crystal silicon is formed on a buried insulating layer made of a silicon oxide film or the like. In this case, a parasitic capacitance, a parasitic resistance and a parasitic conductance can be reduced, thus leading to an improved working speed of the semiconductor integrated circuit device. Additionally, because of the prevention of latch-up, the reliability of the semiconductor integrated circuit device can be improved.

Further, a so-called epitaxial wafer wherein an epitaxial layer is formed on the main surface of a semiconductor substrate may be used. In this case, the properties of the gate insulating film can be improved, thus enabling the performance and reliability of the semiconductor integrated circuit device to be improved.

In the foregoing, the present invention has been described with respect to applications to SRAM-built-in microprocessors encompassing the field of utility, to which the invention is directed. The invention is not limited to such applications as mentioned above, but may be applied, for example, to other types of semiconductor integrated circuit devices having SRAM built therein or SRAM alone.

The effects of the invention obtained by typical embodiments of the invention are summarized below.

(1) According to the invention, a pair of semiconductor regions for source•drain in at least one field effect transistor of an SRAM cell having a complementary metal insulator semiconductor structure is arranged to have an offset structure, so that the GIDL current in the SRAM cell can be reduced, making it possible to significantly reduce consumption power of a semiconductor integrated circuit device having a plurality of SRAM cells.

(2) According to the invention, a gate insulating film of at least one filed effect transistor of an SRAM cell having a complementary metal insulator semiconductor structure is made thicker than a gate insulating film of other field effect transistors supplied with the same source voltage as the at least one field effect transistor, so that the GIDL current in the SRAM cell can be reduced, making it possible to significantly reduce consumption power of a semiconductor integrated circuit device having a plurality of SRAM cells.

(3) According to the invention, the impurity concentration in a low impurity concentration semiconductor region of a pair of semiconductor regions for source•drain of at least one field effect transistor of an SRAM having a complementary metal insulator semiconductor field effect transistor is made lower than the impurity concentration in a low impurity concentration semiconductor region of a pair of semiconductor regions for source•drain of other field effect transistors supplied with the same source voltage as the at least one field effect transistor. As a result, the GIDL current in the SRAM cell can be reduced, thus making it possible to significantly reduce consumption power of a semiconductor integrated circuit device having a plurality of SRAM cells.

(4) According to the invention, a pair of semiconductor regions for source•drain in field effect transistors other than field effect transistors constituting an SRAM cell having a complementary metal insulator semiconductor structure is arranged to have a non-offset structure, thus enabling a semiconductor integrated circuit device having the SRAM to be operated at a high speed.

What is claimed is:

1. A semiconductor integrated circuit device comprising:
a plurality of complementary field effect transistors based SRAM cells each constituted of a plurality of field effect transistors and formed on a semiconductor substrate, wherein at least one first field effect transistor selected from among the plurality of field effect transistors has a pair of semiconductor regions constituting a source and a drain thereof in such a way that end portions at a channel forming region side of the pair of semiconductor regions are located in a direction kept away from opposite ends of a gate electrode so as not to be superposed with the gate electrode of the first field effect transistor; and
a second field effect transistor, which is formed on said semiconductor substrate and is other than said at least one first field effect transistor, having a pair of semiconductor regions wherein end portions at a channel forming region side of said pair of semiconductor regions are partially superposed with a gate electrode of said at least one first field effect transistor.

2. A semiconductor integrated circuit device comprising:
a plurality of complementary field effect transistors based SRAM cells each constituted of a plurality of field effect transistors and formed on a semiconductor substrate, wherein at least one first field effect transistor selected from among the plurality of field effect transistors has a source or drain region in an offset structure with a gate electrode.

3. A semiconductor integrated circuit device comprising:
a plurality of complementary field effect transistors based SRAM cells each constituted of a plurality of field effect transistors and formed on a semiconductor substrate, wherein at least one first field effect transistor selected from among the plurality of field effect transistors has a thickness greater than a gate insulating film of a second field effect transistor which is formed on the semiconductor substrate, is other than said at least one first field effect transistor and is supplied with the same source voltage as said at least one first field effect transistor.

4. A semiconductor integrated circuit device according to claim 3, wherein said at least one first field effect transistor has an offset structure established between a source or drain region and a gate electrode thereof, and said second field effect transistor has a non-offset structure established between a source or drain region and a gate electrode thereof.

5. A semiconductor integrated circuit device comprising:
a plurality of complementary field effect transistors based SRAM cells each constituted of a plurality of field effect transistors and formed on a semiconductor substrate, wherein at least one first field effect transistor selected from among the plurality of field effect transistors has a semiconductor region for source or drain having a first semiconductor region of a relatively low impurity concentration located at a channel forming region side and a second semiconductor region of a relatively high impurity concentration connected to said first semiconductor region; and
a second field effect transistor which is formed on said semiconductor substrate, is other than said at least one first field effect transistor and is supplied with the same source voltage as said at least one first field effect transistor, said second field effect transistor including a semiconductor region for source or drain that has a first semiconductor region of a relatively low impurity concentration located at a channel forming region side and a second semiconductor region of a relatively high impurity concentration connected to said first semiconductor region,
wherein the impurity concentration of said first semiconductor region of said at least one first field effect transistor is lower than the impurity concentration of said first semiconductor region of said second field effect transistor.

6. A semiconductor integrated circuit device according to claim 5, wherein said at least one first field effect transistor and said second field effect transistor, respectively, have a non-offset structure established between a source or drain region and a gate electrode thereof.

7. A semiconductor integrated circuit device according to claim 5, wherein said first field effect transistor has an offset structure established between a source or drain region and a gate electrode thereof, and said second field effect transistor has a non-offset structure established between a source or drain region and a gate electrode thereof.

8. A semiconductor integrated circuit device according to claim 5, wherein said first field effect transistor has a gate insulating film thicker than a gate insulating film of said second field effect transistor.

9. A semiconductor integrated circuit device according to claim 1, wherein a field effect transistor for load of said SRAM cell is constituted of said first field effect transistor, and a field effect transistor for drive and selection of said SRAM cell is constituted of said second field effect transistor.

10. A semiconductor integrated circuit device according to claim 1, wherein a field effect transistor for load and drive of said SRAM cell is constituted of said first field effect transistor, and a field effect transistor for selection of said SRAM cell is constituted of said second field effect transistor.

11. A semiconductor integrated circuit device according to claim 1, wherein a field effect transistor for drive and selection of said SRAM cell is constituted of said first field effect transistor.

12. A semiconductor integrated circuit device according to claim 9, wherein said field effect transistor for load is made of a p-channel field effect transistor.

13. A semiconductor integrated circuit device according to claim 1, wherein a field effect transistor constituting a peripheral circuit of the SRAM formed on said semiconductor substrate, a logic circuit other than the SRAM cell and formed on said semiconductor substrate, or both circuits thereof is constituted of said second field effect transistor.

14. A semiconductor integrated circuit device according to claim 1, wherein said circuit device is electrically assembled in a portable electronic device capable of being driven with a secondary cell.

15. A method for manufacturing a semiconductor integrated circuit device, comprising the steps of:
forming, on a semiconductor substrate, a plurality of field effect transistors constituting each of a plurality of complementary field effect transistors based SRAM cells and a plurality of field effect transistors constituting circuits other than said SRAM cells; and
forming semiconductor regions of at least one first field effect transistor selected from among the plurality of field effect transistors and a second field effect transistor selected from among the plurality of field effect transistors and other than said at least one first field effect transistor in such a way that a semiconductor region for source or drain and a gate electrode of said at least one first field effect transistor are arranged to be offset, and a semiconductor region for source or drain and a gate electrode of said second field effect transistor are arranged to be non-offset.

16. A method for manufacturing a semiconductor integrated circuit decide, comprising the steps of:
(a) forming gate insulating films of first and second field effect transistors on a semiconductor substrate;
(b) forming gate electrodes of said first and second field effect transistors on the gate insulating films, respectively;
(c) covering a forming region of the first field effect transistor to form a mask for exposing a forming region of the second field effect transistor and introducing a first impurity into said semiconductor substrate so that a first semiconductor region, which is a semiconductor region for source or drain of said second field effect transistor having a relatively low impurity concentration, is formed self-alignedly relative to the gate electrode of said second field effect transistor; and
(d) forming a side wall insulating film on side walls of the respective gate electrodes of said first and second field effect transistors and introducing a second impurity into said semiconductor substrate so that a second semiconductor region, which is a semiconductor region for source or drain of said second field effect transistor having a relatively high impurity concentration, is formed self-alignedly relative to the gate electrodes and said side wall insulating films of said first and second field effect transistors.

17. A method for manufacturing a semiconductor integrated circuit device, comprising the steps of:
forming, on a semiconductor substrate, a plurality of field effect transistors constituting each of a plurality of complementary field effect transistors based SRAM cells and a plurality of field effect transistors forming circuits other than the SRAM cells; and
forming a gate insulating film of at least one first field effect transistor selected among from a plurality of field effect transistors constituting the SRAM cell in a thickness larger than a gate insulating film of a second field effect transistor which is other than said first field effect transistor and is supplied with the same source voltage as said first field effect transistor.

18. A method for manufacturing a semiconductor integrated circuit device according to claim 17, comprising the steps of:
(a) forming a first gate insulating film over a main surface of said semiconductor substrate;
(b) selectively removing said first gate insulating film formed over the first field effect transistor-forming region; and
(c) after the step (b), forming a second gate insulting film over the main surface of said semiconductor substrate.

19. A method for manufacturing a semiconductor integrated circuit device according to claim 17, wherein semiconductor regions for source or drain of said first field effect transistor and said second field effect transistor are arranged such that the semiconductor region for source or drain of said first field effect transistor is in offset relation with a gate electrode thereof and the semiconductor region for source or drain of said second field effect transistor is in non-offset relation with a gate electrode thereof.

20. A method for manufacturing a semiconductor integrated circuit device according to claim 15, wherein a field effect transistor for load of the SRAM cell is formed of said first field effect transistor, and a field effect transistor for drive and selection of the SRAM cell is formed of said second field effect transistor.

21. A method for manufacturing a semiconductor integrated circuit device according to claim 15, wherein a field effect transistor for load and drive of the SRAM cell is formed of said first field effect transistor, and a field effect transistor for selection of the SRAM cell is formed of said second field effect transistor.

22. A method for manufacturing a semiconductor integrated circuit device according to claim 15, wherein a field effect transistor for load resistance, drive and selection of the SRAM cell is formed of said first field effect transistor.

23. A method for manufacturing a semiconductor integrated circuit device according to claim 20, wherein the field effect transistor for load is formed of a p-channel field effect transistor.

24. A method for manufacturing a semiconductor integrated circuit device according to claim 15, wherein a field effect transistor constituting a peripheral circuit of an SRAM formed on said semiconductor substrate, a logic circuit formed on said semiconductor substrate, or both is formed of said second field effect transistor.

25. A semiconductor integrated circuit device comprising an SRAM cell having a first n-channel MISFET, a second n-channel MISFET, a first p-channel MISFET and a second p-channel MISFET, wherein source and drains regions of the n-channel MISFET's and the p-channel MISFET's are formed within a semiconductor substrate such that a drain region of the first n-channel MISFET, a drain region of the first p-channel MISFET, a gate electrode of the second n-channel MISFET, and a gate electrode of the second p-channel MISFET are electrically connected with one another, and a drain region of the first n-channel MISFET, a drain region of the first p-channel MISFET, a gate electrode of the second n-channel MISFET, and a gate electrode of the second p-channel MISFET are electrically connected with one another, at least one of the n-channel MISFET and the p-channel MISFET having an offset structure established between the drain region and the gate electrode thereof.

26. A semiconductor integrated circuit device according to claim 25, wherein both n-channel MISFET and p-channel MISFET are constituted of an offset structure.

27. A semiconductor integrated circuit device according to claim 25, wherein the p-channel MISFET is constituted of an offset structure.

28. A semiconductor integrated circuit device according to claim 25, wherein the n-channel MISFET is constituted of an offset structure.

29. A semiconductor integrated circuit device comprising an SRAM cell having a first n-channel MISFET, a second n-channel MISFET, a first p-channel MISFET and a second p-channel MISFET, wherein source and drains regions of the n-channel MISFET's and the p-channel MISFET's are formed within a semiconductor substrate such that a drain region of the first n-channel MISFET, a drain region of the first p-channel MISFET, a gate electrode of the second n-channel MISFET, and a gate electrode of the second p-channel MISFET are electrically connected with one another, and a drain region of the first n-channel MISFET, a drain region of the first p-channel MISFET, a gate electrode of the second n-channel MISFET, and a gate electrode of the second p-channel MISFET are electrically connected with one another, at least one of the n-channel MISFET and the p-channel MISFET being arranged such that the drain region thereof is distant in a direction of being kept away from an end portion of the gate electrode.

30. A semiconductor integrated circuit device according to claim 29, wherein both the n-channel MISFET and the p-channel MISFET are so arranged that the drain regions thereof are distant in a direction of being kept away from an end portion of the gate electrode thereof.

31. A semiconductor integrated circuit device according to claim 29, wherein the p-channel MISFET is so arranged that the drain region thereof is distant in a direction of being kept away from an end portion of the gate electrode thereof.

32. A semiconductor integrated circuit device according to claim 29, wherein the n-channel MISFET is located so that the drain region thereof is distant in a direction of being kept away from an end portion of the gate electrode thereof.

33. A semiconductor integrated circuit device comprising an SRAM cell and a peripheral circuit, said SRAM having a first n-channel MISFET, a second n-channel MISFET, a first p-channel MISFET and a second p-channel MISFET, wherein source and drains regions of the n-channel MISFET's and the p-channel MISFET's are formed within a semiconductor substrate such that a drain region of the first n-channel MISFET, a drain region of the first p-channel MISFET, a gate electrode of the second n-channel MISFET, and a gate electrode of the second p-channel MISFET are electrically connected with one another, and a drain region of the first n-channel MISFET, a drain region of the first p-channel MISFET, a gate electrode of the second n-channel MISFET, and a gate electrode of the second p-channel MISFET are electrically connected with one another, said peripheral circuit including an n-channel MISFET and a p-channel MISFET, wherein an impurity concentration at a portion contacting the channel region of the drain region of the p-channel MISFET of the SRAM cell is lower than an impurity concentration at a portion contacting the channel region of the drain region of the p-channel MISFET of said peripheral circuit.

34. A semiconductor integrated circuit device according to claim 33, wherein an impurity concentration at a portion contact the channel region of the drain region of the n-channel MISFET of the SRAM cell is lower than an impurity concentration at a portion contacting the channel region of the drain region of the n-channel MISFET of said peripheral circuit.

35. A semiconductor integrated circuit device comprising an SRAM cell and a peripheral circuit, said SRAM having a first n-channel MISFET, a second n-channel MISFET, a first p-channel MISFET and a second p-channel MISFET, wherein source and drains regions of the n-channel MISFET's and the p-channel MISFET's are formed within a semiconductor substrate such that a drain region of the first n-channel MISFET, a drain region of the first p-channel MISFET, a gate electrode of the second n-channel MISFET, and a gate electrode of the second p-channel MISFET are electrically connected with one another, and a drain region of the first n-channel MISFET, a drain region of the first p-channel MISFET, a gate electrode of the second n-channel MISFET, and a gate electrode of the second p-channel MISFET are electrically connected with one another, said peripheral circuit including an n-channel MISFET and a p-channel MISFET, wherein an impurity concentration at a portion contacting the channel region of the drain region of the n-channel MISFET of the SRAM cell is lower than an impurity concentration at a portion contacting the channel region of the drain region of the n-channel MISFET of said peripheral circuit.

36. A semiconductor integrated circuit device comprising source and drain regions of each of MISFET's constituting an SRAM cell formed within a semiconductor substrate in such a way that the drain region and a gate electrode are arranged to have an offset structure.

37. A semiconductor integrated circuit device comprising source and drain regions of each of MISFET's constituting an SRAM cell formed within a semiconductor substrate in such a way that the drain region is arranged to be distant in a direction of being kept away from an end portion of a gate electrode.

38. A semiconductor integrated circuit device comprising source and drain regions of each of MISFET's constituting an SRAM cell formed within a semiconductor substrate in such a way that an impurity concentration at a portion contacting a channel region of the drain region is lower than an impurity concentration at a portion contacting a channel portion of a drain region of MISFET of a peripheral circuit.

39. A method for manufacturing a semiconductor integrated circuit device, comprising the steps of:
(a) forming a gate electrode having a first silicon film formed on a gate insulating film, an SiGe layer formed on the first silicon film and a second silicon film formed on the SiGe film; and
(b) after the step (a), forming a silicide film at least on the second silicon film.

40. A method for manufacturing a semiconductor integrated circuit device according to claim 39, wherein in the step of forming the gate electrode, a gate electrode of a p-channel MISFET and a gate electrode of an n-channel MISFET are both formed.

41. A method for manufacturing a semiconductor integrated circuit device according to claim 39 or 40, wherein a concentration of Ge in the SiGe layer is so set that a work function of the gate electrode is at a level between a work function of a p-type silicon film and a work function of an n-type silicon film.

42. A method for manufacturing a semiconductor integrated circuit device, comprising the steps of:
(a) depositing a first silicon film on a gate insulating film;
(b) depositing an SiGe layer on the first silicon film;
(c) depositing a second silicon film on the SiGe layer;
(d) pattering the second silicon film, the SiGe layer and the first silicon film to form a gate electrode of a p-channel MISFET and a gate electrode of an n-channel MISFET; and
(e) forming a silicide film at least on the second silicon film.

43. A method for manufacturing a semiconductor integrated circuit device according to claim 42, wherein a concentration of Ge in the SiGe layer is so set that a work function of the gate electrode is at a level between a work function of a p-type silicon film and a work function of an n-type silicon film.

44. A method for manufacturing a semiconductor integrated circuit device according to claim 42 or 43, wherein the silicide film is formed by silicifying the second silicon film.

45. A method for manufacturing a semiconductor integrated circuit device according to claim 42 or 43, wherein the gate insulating film is formed of a silicon oxide nitride film.

46. A semiconductor integrated circuit device comprising:
a gate electrode including a first silicon film formed on a gate insulating film, an SiGe film formed on the first silicon film, and a second silicon film formed on the SiGe film; and
a silicide film formed at least on the second silicon film.

47. A semiconductor integrated circuit device according to claim 46, wherein a concentration of Ge in the SiGe layer is so set that a work function of the gate electrode is at a level between a work function of a p-type silicon film and a work function of an n-type silicon film.

48. A semiconductor integrated circuit device according to claim 46 or 47, wherein the gate insulating film is formed of a silicon oxide nitride film.

49. A semiconductor integrated circuit device comprising:
gate electrodes of a p-channel MISFET and an n-channel MISFET, each having a first silicon film formed on a gate insulating film, an SiGe film formed on the first silicon film and a second silicon film formed on the SiGe film; and
a silicide film formed at lest on the second silicon film.

50. A semiconductor integrated circuit device according to claim 49, wherein a concentration of Ge in the SiGe layer is so set that a work function of the gate electrode is at a level between a work function of a p-type silicon film and a work function of an n-type silicon film.

51. A semiconductor integrated circuit device according to claim 49 or 50, wherein the gate insulating film is formed of a silicon oxide nitride film.
